(19) United States
(12) Patent Application Publication
(10) Pub. No.: US 2026/0324198 A1
(43) Pub. Date: Oct. 15, 2026

(54) DISPLAY PANEL AND DISPLAY APPARATUS

(71) Applicants: Beijing BOE Technology Development Co., Ltd., Beijing (CN); BOE Technology Group Co., Ltd., Beijing (CN)

(72) Inventors: Jinglu Bai, Beijing (CN); Cheng Zeng, Beijing (CN); Jian Xu, Beijing (CN)

(73) Assignees: Beijing BOE Technology Development Co., Ltd., Beijing (CN); BOE Technology Group Co., Ltd., Beijing (CN)

(21) Appl. No.: 18/727,155

(22) PCT Filed: Nov. 21, 2023
(86) PCT No.: PCT/CN2023/132788

§ 371 Date: Jul. 8, 2024

(51) Int. Cl. H10K 59/122; H10K 59/38; H10K 59/80

(52) U.S. Cl. CPC H10K 59/122; H10K 59/38; H10K 59/873; H10K 59/8792

(57) ABSTRACT

A display panel is provided. The display panel includes a plurality of light emitting elements; a first encapsulating layer on the plurality of light emitting elements; a color conversion layer including a plurality of color conversion blocks on a side of the first encapsulating layer away from the plurality of light emitting elements; a color filter on a side of the color conversion layer away from the first encapsulating layer; and a second encapsulating layer on a side of the color filter away from the color conversion layer. The second encapsulating layer includes at least an organic encapsulating sublayer.

### TECHNICAL FIELD

The present invention relates to display technology, more particularly, to a display panel and a display apparatus.

### BACKGROUND

Quantum dots material has excellent optical and electrical properties, including a narrow emission peak (with a half-peak width of approximately 30 nm), a tunable spectrum (ranging from visible light to infrared light), high photochemical stability, and a low starting voltage. Wavelengths of light emitted from quantum dots materials are tunable at least in part based on the particle sizes of the quantum dots. Due to these excellent properties, quantum dots have become a focus of research and development in the fields of display technology.

### SUMMARY

In one aspect, the present disclosure provides a display panel, comprising a plurality of light emitting elements; a first encapsulating layer on the plurality of light emitting elements; a color conversion layer comprising a plurality of color conversion blocks on a side of the first encapsulating layer away from the plurality of light emitting elements; a color filter on a side of the color conversion layer away from the first encapsulating layer; and a second encapsulating layer on a side of the color filter away from the color conversion layer; wherein the second encapsulating layer comprises at least an organic encapsulating sublayer.

Optionally, the display panel further comprises a first cap layer on a side of the color conversion layer away from the first encapsulating layer, and on side of the color filter away from the second encapsulating layer; and a second cap layer on a side of the first encapsulating layer away from the plurality of light emitting elements, and on a side of the color conversion layer away from the first cap layer; wherein the color filter is in direct contact with the first cap layer.

Optionally, the color filter comprises a first color filter layer of a first color, a second color filter layer of a second color on the first color filter layer of the first color, and a third color filter layer of a third color on a side of the second color filter layer of the second color away from the first color filter layer of the first color; wherein the first color, the second color, and the third color are three different colors selected from a green color, a red color, and a blue color.

Optionally, the display panel further comprises a bank layer; and a plurality of first apertures and a plurality of second apertures extending through the bank layer; wherein the plurality of first apertures and the plurality of second apertures are in a display area of the display panel; the plurality of first apertures are configured to receive the plurality of color conversion blocks; and the plurality of color conversion blocks are absent in the plurality of second apertures.

Optionally, a portion of the color filter is at least partially in a respective second aperture of the plurality of second apertures.

Optionally, in a portion of a light non-transmissive region comprising a respective second aperture of the plurality of second apertures, comprising a stacked structure comprising at least two of a portion of a first color filter layer of a first color, a portion of a second color filter layer of a second color on the portion of the first color filter layer of the first color, or a portion of a third color filter layer of a third color on a side of the portion of the second color filter layer of the second color away from the portion of the first color filter layer of the first color.

Optionally, the respective second aperture is configured to receive a portion of a first color filter layer of a first color.

Optionally, along a plane intersecting two adjacent color filter blocks and perpendicular to a surface of the first encapsulating layer: a portion of the first color filter layer of the first color in a portion of a light transmissive region comprising a first aperture of the plurality of first apertures has a first thickness; a portion of the first color filter layer of the first color in a portion of a light non-transmissive region comprising a second aperture of the plurality of second apertures has a second thickness; the bank layer has a third thickness; the second thickness is greater than the first thickness; and a difference between the second thickness and the first thickness is substantially the same as the third thickness.

Optionally, the respective second aperture is configured to receive a portion of a first color filter layer of a first color and a portion of a second color filter layer of a second color.

Optionally, along a plane intersecting two adjacent color filter blocks and perpendicular to a surface of the first encapsulating layer: a portion of the first color filter layer of the first color in a portion of a light transmissive region comprising a first aperture of the plurality of first apertures has a first thickness; a portion of the first color filter layer of the first color in a portion of a light non-transmissive region comprising a second aperture of the plurality of second apertures has a second thickness; a portion of the second color filter layer of the second color in a portion of a light transmissive region comprising a first aperture of the plurality of first apertures has a fourth thickness; a portion of the second color filter layer of the second color in a portion of a light non-transmissive region comprising a second aperture of the plurality of second apertures has a fifth thickness; the bank layer has a third thickness; the second thickness is greater than the first thickness; the fifth thickness is greater than the fourth thickness; a difference between the second thickness and the first thickness is substantially the same as the third thickness; and a difference between the fifth thickness and the fourth thickness is substantially the same as the third thickness.

Optionally, the display panel further comprises a first cap layer on a side of the color conversion layer away from the first encapsulating layer, and on side of the color filter away from the second encapsulating layer; wherein the portion of the first color filter layer of the first color inside the respective second aperture is in direct contact with a portion of the first cap layer inside the respective second aperture.

Optionally, the display panel further comprises a first cap layer on a side of the color conversion layer away from the first encapsulating layer, and on side of the color filter away from the second encapsulating layer; wherein the portion of the first color filter layer of the first color inside the respective second aperture is in direct contact with a portion of the first cap layer inside the respective second aperture; and the portion of the second color filter layer of the second color inside the respective second aperture is in direct contact with the portion of the first cap layer inside the respective second aperture.

Optionally, the respective second aperture is configured to receive a portion of a first color filter layer of a first color, a portion of a second color filter layer of a second color, and a portion of a third color filter of a third color.

Optionally, the display panel further comprises a black matrix; wherein the respective second aperture is configured to receive a portion of the black matrix.

Optionally, the display panel further comprises a bank layer; and a groove extending at least partially into the bank layer; wherein the groove is in a non-display area of the display panel; and the groove substantially surrounds a display area of the display panel.

Optionally, a portion of the second encapsulating layer is at least partially inside the groove.

Optionally, the display panel further comprises a plurality of third apertures extending at least partially into the bank layer; wherein the plurality of third apertures are in the non-display area; a combination of the plurality of third apertures substantially surrounds the display area; and the groove substantially surrounds the combination of the plurality of third apertures.

Optionally, a portion of the second encapsulating layer is at least partially inside a respective third aperture of the plurality of third apertures.

Optionally, the display panel comprises a quantum dots material at least partially inside a respective third aperture of the plurality of third apertures.

Optionally, the display panel comprises a quantum dots material at least partially inside a third aperture of the plurality of third apertures on a first side or a second side of the display area; wherein quantum dots material is absent in a third aperture of the plurality of third apertures on a third side or a fourth side of the display area; the first side is opposite to the second side; and the third side is opposite to the fourth side.

Optionally, the display panel further comprises a first cap layer on a side of the color conversion layer away from the first encapsulating layer, and on side of the color filter away from the second encapsulating layer; wherein a quantum dots material is at least partially inside the groove; a portion of the second encapsulating layer is at least partially inside the groove; and a quantum dots material is at least partially inside a respective third aperture of the plurality of third apertures; wherein a surface of the quantum dots material in the respective third aperture in direct contact with the first cap layer has a first height relative to a surface of a first base substrate; a surface of the quantum dots material in the groove in direct contact with the portion of the second encapsulating layer inside the groove has a second height relative to a surface of the first base substrate; and the first height is greater than the second height.

In another aspect, the present disclosure provides a display apparatus, comprising the display panel described herein or fabricated by the method described herein, and one or more integrated circuits connected to the display panel.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a display panel in some embodiments according to the present disclosure.

FIG. 2 is a cross-sectional view along an A-A′ line in FIG. 1.

FIG. 3 is a plan view of a display panel in some embodiments according to the present disclosure.

FIG. 4 is a cross-sectional view of a display panel in some embodiments according to the present disclosure.

FIG. 5 is a cross-sectional view of a display panel in some embodiments according to the present disclosure.

FIG. 6A is a schematic diagram illustrating the structure of a light emitting element in some embodiments according to the present disclosure.

FIG. 6B is a schematic diagram illustrating the structure of a light emitting element in some embodiments according to the present disclosure.

FIG. 6C is a schematic diagram illustrating the structure of a light emitting element in some embodiments according to the present disclosure.

FIG. 7A is a schematic diagram illustrating the structure of a first color conversion block in some embodiments according to the present disclosure.

FIG. 7B is a schematic diagram illustrating the structure of a second color conversion block in some embodiments according to the present disclosure.

FIG. 7C is a schematic diagram illustrating the structure of a light transmissive block in some embodiments according to the present disclosure.

FIG. 8 is a schematic diagram illustrating the structure of a display panel in some embodiments according to the present disclosure.

FIG. 9 is a cross-sectional view along a C-C′ line in FIG. 8.

FIG. 10 is a plan view of a display panel in some embodiments according to the present disclosure.

FIG. 11 is a cross-sectional view of a display panel in some embodiments according to the present disclosure.

FIG. 12 is a cross-sectional view of a display panel in some embodiments according to the present disclosure.

FIG. 13 illustrates a plurality of first apertures and a plurality of second apertures in a color conversion substrate in some embodiments according to the present disclosure.

FIG. 14 illustrates a color filter in a color conversion substrate in some embodiments according to the present disclosure.

FIG. 15A to FIG. 15E illustrate a process of fabricating a color conversion substrate in some embodiments according to the present disclosure.

FIG. 16 is a cross-sectional view of a display panel in some embodiments according to the present disclosure.

FIG. 17 illustrates a plurality of first apertures and a plurality of second apertures in a color conversion substrate in some embodiments according to the present disclosure.

FIG. 18 illustrates a color filter in a color conversion substrate in some embodiments according to the present disclosure.

FIG. 19 is a cross-sectional view of a display panel in some embodiments according to the present disclosure.

FIG. 20 illustrates a plurality of first apertures and a plurality of second apertures in a color conversion substrate in some embodiments according to the present disclosure.

FIG. 21 illustrates a color filter in a color conversion substrate in some embodiments according to the present disclosure.

FIG. 22 is a cross-sectional view of a display panel in some embodiments according to the present disclosure.

FIG. 23 illustrates a plurality of first apertures and a plurality of second apertures in a color conversion substrate in some embodiments according to the present disclosure.

FIG. 24 illustrates a color filter in a color conversion substrate in some embodiments according to the present disclosure.

FIG. 25 is a cross-sectional view of a display panel in some embodiments according to the present disclosure.

FIG. 26 illustrates a plurality of first apertures and a plurality of second apertures in a color conversion substrate in some embodiments according to the present disclosure.

FIG. 27 illustrates a color filter in a color conversion substrate in some embodiments according to the present disclosure.

FIG. 28 illustrates a subpixel arrangement in a display panel in some embodiments according to the present disclosure.

FIG. 29 illustrates a subpixel arrangement in a display panel in some embodiments according to the present disclosure.

FIG. 30 illustrates a subpixel arrangement in a display panel in some embodiments according to the present disclosure.

FIG. 31 illustrates a subpixel arrangement in a display panel in some embodiments according to the present disclosure.

FIG. 32 is a plan view of a display panel in some embodiments according to the present disclosure.

FIG. 33 is a cross-sectional view along a E-E′ line in FIG. 32.

FIG. 34 is a plan view of a display panel in some embodiments according to the present disclosure.

FIG. 35 is a cross-sectional view along an F-F′ line in FIG. 34.

FIG. 36 is a plan view of a display panel in some embodiments according to the present disclosure.

FIG. 37 is a cross-sectional view along a G-G′ line in FIG. 36.

FIG. 38 is a plan view of a display panel in some embodiments according to the present disclosure.

FIG. 39 is a cross-sectional view along an H-H′ line in FIG. 36.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

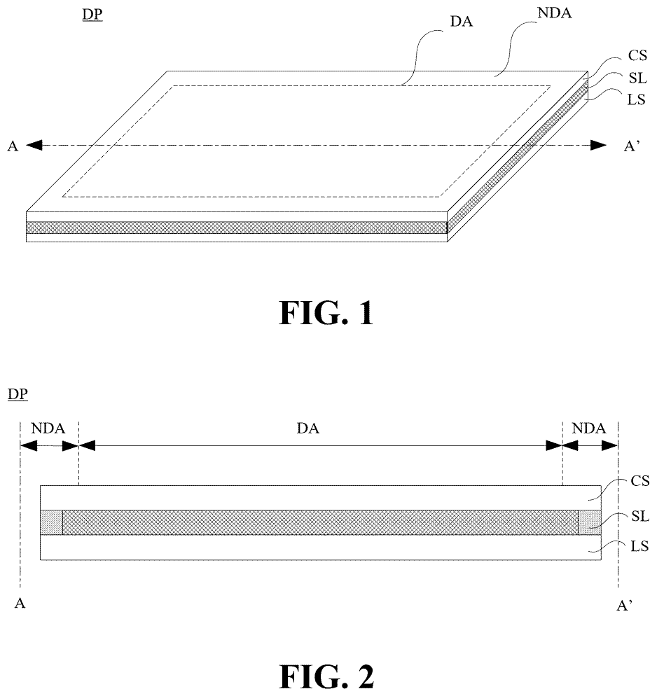

FIG. 1 is a schematic diagram illustrating the structure of a display panel in some embodiments according to the present disclosure. FIG. 2 is a cross-sectional view along an A-A′ line in FIG. 1. Referring to FIG. 1 and FIG. 2, the display panel DP in some embodiments includes a light emitting substrate LS, a color conversion substrate CS, and a spacer layer SL spacing apart the light emitting substrate LS and the color conversion substrate CS. The display panel DP includes a display area DA and a non-display area NDA. As used herein, the term “display area” refers to an area of a display substrate (e.g., a color conversion substrate or a light emitting substrate) in a display panel where image is actually displayed. Optionally, the display area may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels. As used herein the term “non-display area” refers to an area of a display substrate (e.g., a color conversion substrate or a light emitting substrate) in a display panel where various circuits and wires are provided to transmit signals to the display substrate. To increase the transparency of the display apparatus, non-transparent or opaque components of the display apparatus (e.g., battery, printed circuit board, metal frame), can be disposed in the non-display area rather than in the display areas.

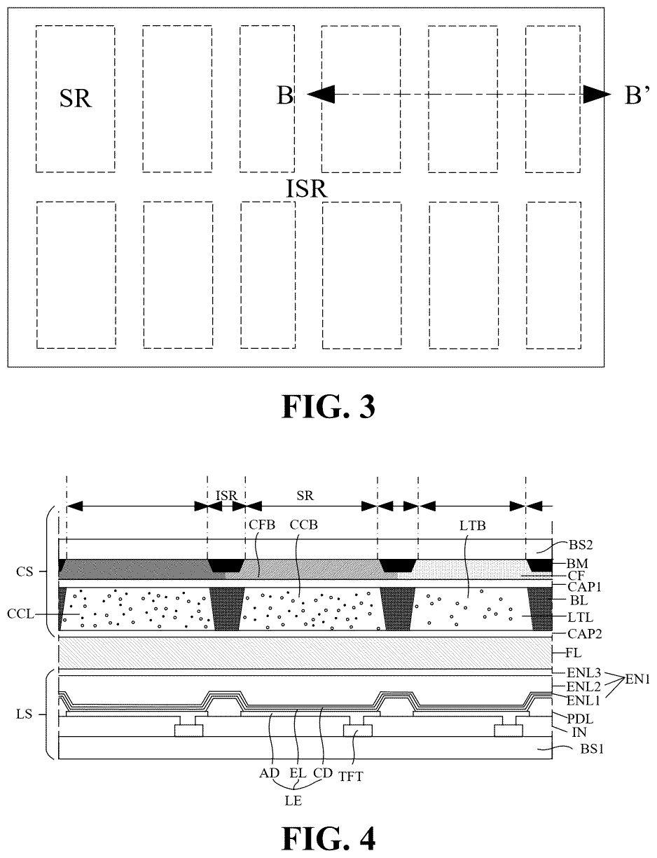

FIG. 3 is a plan view of a display panel in some embodiments according to the present disclosure. Referring to FIG. 3, the display panel in some embodiments includes a plurality of subpixel regions SR and an inter-subpixel region ISR. As used herein, a subpixel region refers to a light emission region of a subpixel, such as a region corresponding to a pixel electrode in a liquid crystal display, or a region corresponding to a light emissive layer in a light emitting diode display panel, or a region corresponding to a color conversion block in a display panel according to the present disclosure. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel. As used herein, an inter-subpixel region refers to a region between adjacent subpixel regions, such as a region corresponding to a black matrix in a liquid crystal display, or a region corresponding a pixel definition layer in a light emitting diode display panel, or a region corresponding to a bank layer in a display panel according to the present disclosure. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

Various appropriate implementations may be practiced to make a display panel of the present disclosure. In one example, a light emitting substrate and a color conversion substrate are fabricated respectively, and then assembled together using a filler layer into a display panel. In another example, the color conversion substrate is directly fabricated on the light emitting substrate.

FIG. 4 is a cross-sectional view of a display panel in some embodiments according to the present disclosure. For example, FIG. 4 may be a cross-sectional view along a B-B′ line in the display panel depicted in FIG. 3. Referring to FIG. 4, the display panel in some embodiments includes a light emitting substrate LS and a color conversion substrate CS. The light emitting substrate LS and the color conversion substrate CS are assembled together. In some embodiments, the display panel further includes a filler layer FL between the light emitting substrate LS and the color conversion substrate CS, assembling the light emitting substrate LS and the color conversion substrate CS into the display panel.

Referring to FIG. 4, in some embodiments, the light emitting substrate LS includes a first base substrate BS1; a plurality of thin film transistor TFT (e.g., transistors in pixel driving circuits) on the first base substrate BS1; an insulating layer IN on a side of the plurality of transistor TFT away from the first base substrate BS1; a pixel definition layer PDL and a plurality of light emitting elements LE on a side of the insulating layer IN away from the first base substrate BS1; and a first encapsulating layer EN1 on a side of the plurality of light emitting elements LE and the pixel definition layer PDL away from the first base substrate BS1. A respective light emitting element of the plurality of light emitting elements LE includes an anode AD, a light emitting layer EL on a side of the anode AD away from the first base substrate BS1, and a cathode CD on a side of the light emitting layer EL away from the first base substrate BS1. In one example, the first encapsulating layer EN1 include a first inorganic encapsulating sublayer ENL1, a first organic encapsulating sublayer ENL2 on a side of the first inorganic encapsulating sublayer ENL1 away from the first base substrate BS1, and a second inorganic encapsulating sublayer ENL3 on a side of the first organic encapsulating sublayer ENL2 away from the first base substrate BS1.

Referring to FIG. 4, in some embodiments, the color conversion substrate CS includes a bank layer BL defining a plurality of apertures, a color conversion layer CCL and a light transmissive layer LTL at least partially in the plurality of apertures defined by the bank layer BL. The color conversion layer CCL includes a plurality of color conversion blocks CCB. The light transmissive layer LTL includes a plurality of light transmissive blocks LTB.

The color conversion substrate CS in some embodiments further includes a color filter CF on the color conversion layer CCL and the light transmissive layer LTL. The color filter CF includes a plurality of color filter blocks CFB. An orthographic projection of a respective color filter block of the plurality of color filter blocks CFB on a base substrate at least partially overlaps with an orthographic projection of a respective color conversion block or a respective light transmissive block on the base substrate. Orthographic projections of adjacent color filter blocks may partially overlap with each other, e.g., along the edges.

The color conversion substrate CS in some embodiments further includes a black matrix BM on a side of the color filter CF away from the color conversion layer CCL and the light transmissive layer LTL. The black matrix BM is in the inter-subpixel region ISR. A respective color filter block, a respective color conversion block, or a respective light transmissive block is at least partially in an individual subpixel region. Optionally, the color conversion substrate CS includes a first cap layer CAP1 on a side of the bank layer BL, the color conversion layer CCL, and the light transmissive layer LTL closer to the second base substrate BS2. The color conversion substrate CS optionally includes a second cap layer CAP2 on a side of the bank layer BL, the color conversion layer CCL, and the light transmissive layer LTL away from the color filter CF.

In some embodiments, the light transmissive layer LTL is a light scattering layer, and the plurality of light transmissive blocks LTB are a plurality of light scattering blocks.

In some embodiments, the display panel is a quantum dots display panel. In a quantum dots display panel, a light source (e.g., a blue light source) is used to excite quantum dots to emit light based on the photoluminescence excitation principle. In some embodiments, the plurality of color conversion blocks CCB include a first color conversion block and a second color conversion block. In one example, the first color conversion block is configured to convert a light of a third color (e.g., a blue light) into a light of a first color (e.g., a red light). In another example, the second color conversion block is configured to convert the light of the third color (e.g., a blue light) into a light of a second color (e.g., a green light). The plurality of light transmissive blocks LTB do not convert a color of the incident light. Optionally, the plurality of light transmissive blocks LTB are configured to scatter the incident light (e.g., a blue light), which emits through a color filter block for image display. The plurality of color filter blocks CFB includes a color filter block of a first color (e.g., a red color filter block) corresponding to the first color conversion block, a color filter block of a second color (e.g., a green color filter block) corresponding to the second color conversion block, and a color filter block of a third color (e.g., a blue color filter block) corresponding to a light transmissive block.

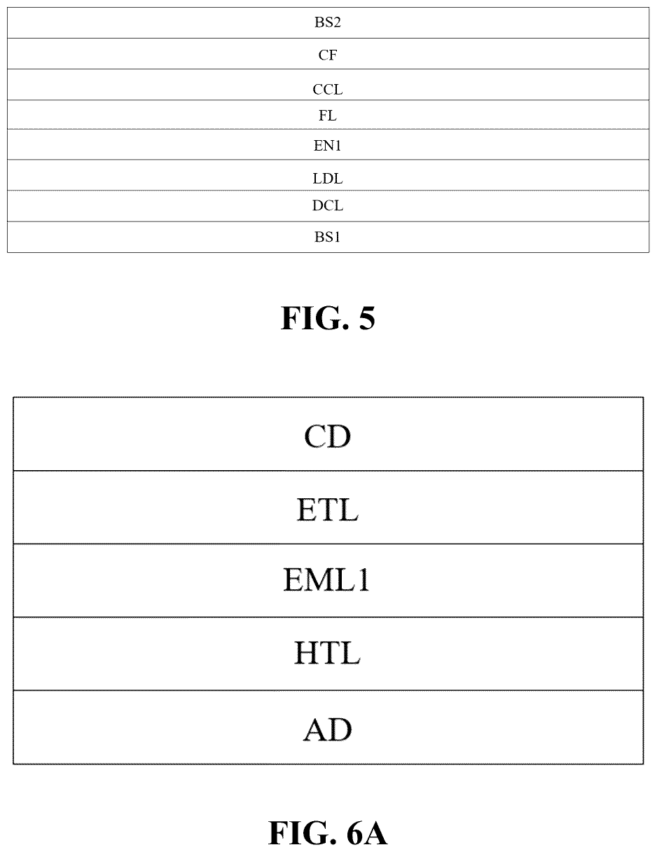

FIG. 5 is a cross-sectional view of a display panel in some embodiments according to the present disclosure. Referring to FIG. 5, the display panel in some embodiments includes a first base substrate BS1, a driving control layer DCL comprising a plurality of transistors configured to control light emission of the display panel on the first base substrate BS1, a light emitting element layer LDL comprising a plurality of light emitting elements on a side of the driving control layer DCL away from the first base substrate BS1, a first encapsulating layer EN1 on a side of the light emitting element layer LDL away from the first base substrate BS1, a filler layer FL on a side of the first encapsulating layer EN1 away from the first base substrate BS1, a color conversion layer CCL on a side of the filler layer FL away from the first base substrate BS1, a color filter CF on a side of the color conversion layer CCL away from the first base substrate BS1, and a second base substrate BS2 on a side of the color filter CF away from the first base substrate BS1.

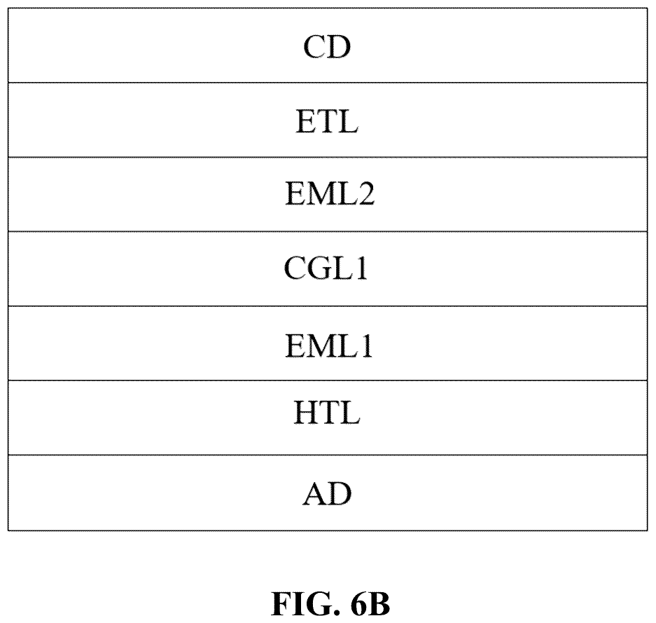

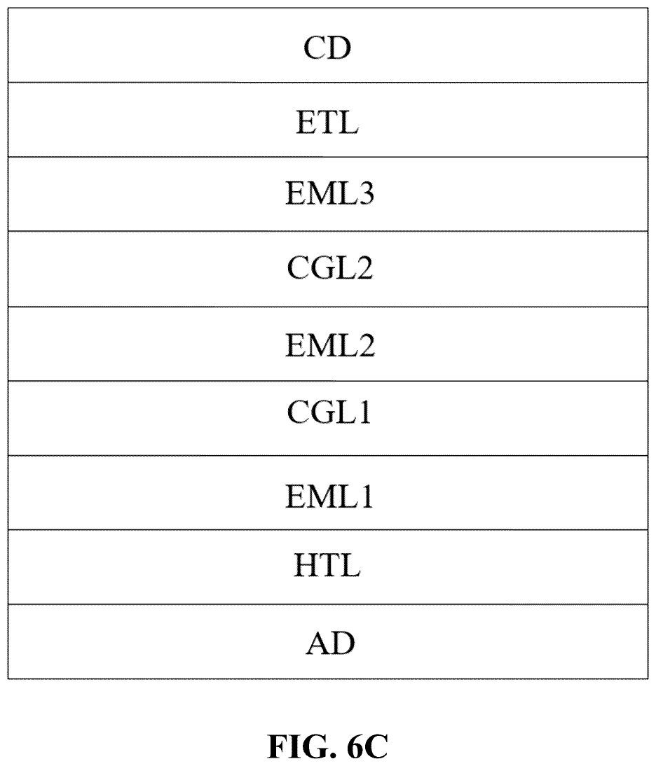

Various appropriate light emitting elements may be implemented in the display panel according to the present disclosure. FIG. 6A is a schematic diagram illustrating the structure of a light emitting element in some embodiments according to the present disclosure. Referring to FIG. 6A, the light emitting element in some embodiments includes an anode AD, a hole transport layer HTL on the anode AD, a first light emitting layer EML1 on a side of the hole transport layer HTL away from the anode AD, an electron transport layer ETL on a side of the first light emitting layer EML1 away from the hole transport layer HTL, and a cathode CD on a side of the electron transport layer ETL away from the first light emitting layer EML1.

In some embodiments, the light emitting element may have a stacked structure. FIG. 6B is a schematic diagram illustrating the structure of a light emitting element in some embodiments according to the present disclosure. Referring to FIG. 6B, the light emitting element in some embodiments includes an anode AD, a hole transport layer HTL on the anode AD, a first light emitting layer EML1 on a side of the hole transport layer HTL away from the anode AD, a first charge generation layer CGL1 on a side of the first light emitting layer EML1 away from the hole transport layer HTL, a second light emitting layer EML2 on a side of the first charge generation layer CGL1 away from the first light emitting layer EML1, an electron transport layer ETL on a side of the second light emitting layer EML2 away from the first charge generation layer CGL1, and a cathode CD on a side of the electron transport layer ETL away from the second light emitting layer EML2.

FIG. 6C is a schematic diagram illustrating the structure of a light emitting element in some embodiments according to the present disclosure. Referring to FIG. 6C, the light emitting element in some embodiments includes an anode AD, a hole transport layer HTL on the anode AD, a first light emitting layer EML1 on a side of the hole transport layer HTL away from the anode AD, a first charge generation layer CGL1 on a side of the first light emitting layer EML1 away from the hole transport layer HTL, a second light emitting layer EML2 on a side of the first charge generation layer CGL1 away from the first light emitting layer EML1, a second charge generation layer CGL2 on a side of the second light emitting layer EML2 away from the first charge generation layer CGL1, a third light emitting layer EML3 on a side of the second charge generation layer CGL2 away from the second light emitting layer EML2, an electron transport layer ETL on a side of the third light emitting layer EML3 away from the second charge generation layer CGL2, and a cathode CD on a side of the electron transport layer ETL away from the third light emitting layer EML3.

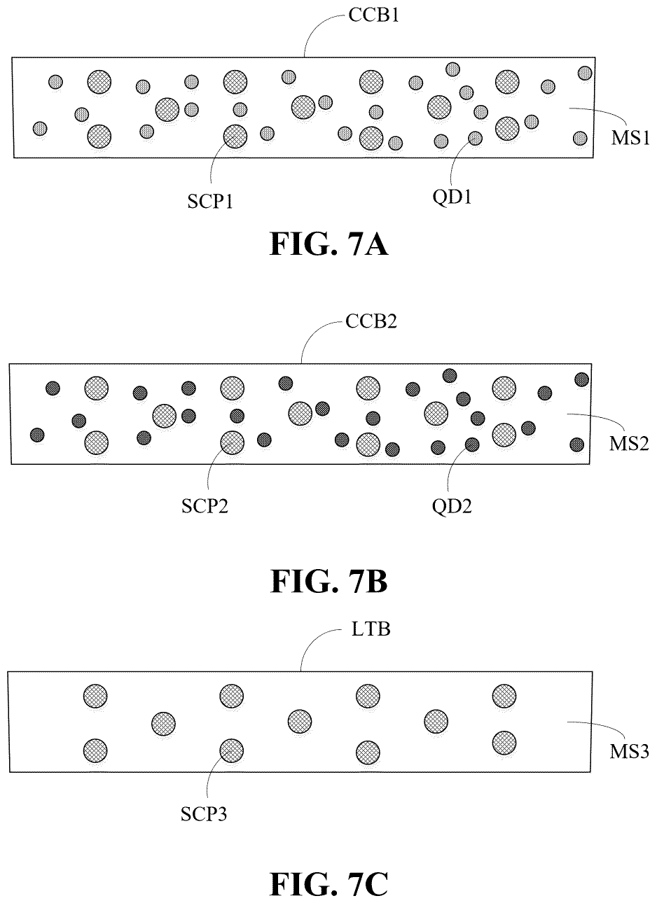

FIG. 7A is a schematic diagram illustrating the structure of a first color conversion block in some embodiments according to the present disclosure. Referring to FIG. 7A, the first color conversion block CCB1 is a color conversion block configured to convert a light of a third color (e.g., a blue light) into a light of a first color (e.g., a red light). In some embodiments, the first color conversion block CCB1 includes a first matrix MS1, a plurality of first scattering particles SCP1 and a plurality of first quantum dots QD1 dispersed in the first matrix MS1. The first matrix MS1 may include a polymer material such as an organic polymer material. Examples of appropriate polymer materials for making the first matrix MS1 include epoxy resins, acrylic resins, polyurethane resins, silicone resins, and silane resins. Examples of appropriate materials for making the plurality of first scattering particles SCP1 include TiO₂, ZnO, ZrO₂, Al₂O₃, SiO₂. Examples of appropriate quantum dots materials for making the plurality of first quantum dots QD1 include a quantum dots material of a first color (e.g., a red color). The quantum dots material may include a material selected from a group consisting of CdS, CdSe, ZnSe, InP, PbS, CsPbC13, CsPbBr3, CsPhI3, CdS/ZnS, CdSe/ZnS, InP/ZnS, PbS/ZnS, CsPbC13/ZnS, CsPbBr3/ZnS, and CsPhI3/ZnS.

FIG. 7B is a schematic diagram illustrating the structure of a second color conversion block in some embodiments according to the present disclosure. Referring to FIG. 7B, the second color conversion block CCB2 is a color conversion block configured to convert a light of a third color (e.g., a blue light) into a light of a second color (e.g., a green light). In some embodiments, the second color conversion block CCB2 includes a second matrix MS2, a plurality of second scattering particles SCP2 and a plurality of second quantum dots QD2 dispersed in the second matrix MS2. The second matrix MS2 may include a polymer material such as an organic polymer material. Examples of appropriate polymer materials for making the second matrix MS2 include epoxy resins, acrylic resins, polyurethane resins, silicone resins, and silane resins. Examples of appropriate materials for making the plurality of second scattering particles SCP2 include TiO₂, ZnO, ZrO₂, Al₂O₃, SiO₂. Examples of appropriate quantum dots materials for making the plurality of second quantum dots QD2 include a quantum dots material of a second color (e.g., a green color). The quantum dots material may include a material selected from a group consisting of CdS, CdSe, ZnSe, InP, PbS, CsPbC13, CsPbBr3, CsPhI3, CdS/ZnS, CdSe/ZnS, InP/ZnS, PbS/ZnS, CsPbC13/ZnS, CsPbBr3/ZnS, and CsPhI3/ZnS.

FIG. 7C is a schematic diagram illustrating the structure of a light transmissive block in some embodiments according to the present disclosure. Referring to FIG. 7C, the light transmissive block LTB in some embodiments includes a third matrix MS3 and a plurality of third scattering particles SCP3 dispersed in the third matrix MS3. The third matrix MS3 may include a polymer material such as an organic polymer material. Examples of appropriate polymer materials for making the third matrix MS3 include epoxy resins, acrylic resins, polyurethane resins, silicone resins, and silane resins. Examples of appropriate materials for making the plurality of third scattering particles SCP3 include TiO₂, ZnO, ZrO₂, Al₂O₃, SiO₂.

In one example, the first matrix MS1, the second matrix MS2, and the third matrix MS3 includes a same polymer material. In another example, at least two of the first matrix MS1, the second matrix MS2, and the third matrix MS3 includes different polymer materials.

In one example, the first scattering particles SCP1, the second scattering particles SCP2, and the third scattering particles SCP3 includes a same scattering material. In another example, at least two of the first scattering particles SCP1, the second scattering particles SCP2, and the third scattering particles SCP3 includes different scattering materials.

The inventors of the present disclosure discover that, in display panels depicted in FIG. 4 and FIG. 5, light emitted from the light emitting element layer LDL has to transmit through the first encapsulating layer EN1 and the filler layer FL before it reaches quantum dots materials in the color conversion layer CCL. The display panels depicted in FIG. 4 and FIG. 5 are prone to light leakage between adjacent subpixels, leading to color shift issues and a decrease in display color purity.

Accordingly, the present disclosure provides, inter alia, a display panel and a display apparatus that substantially obviate one or more of the problems due to limitations and disadvantages of the related art. In one aspect, the present disclosure provides a display panel. In some embodiments, the display panel includes a plurality of light emitting elements; a first encapsulating layer on the plurality of light emitting elements; a color conversion layer comprising a plurality of color conversion blocks on a side of the first encapsulating layer away from the plurality of light emitting elements; a color filter on a side of the color conversion layer away from the first encapsulating layer; and a second encapsulating layer on a side of the color filter away from the color conversion layer. Optionally, the second encapsulating layer comprises at least an organic encapsulating sublayer.

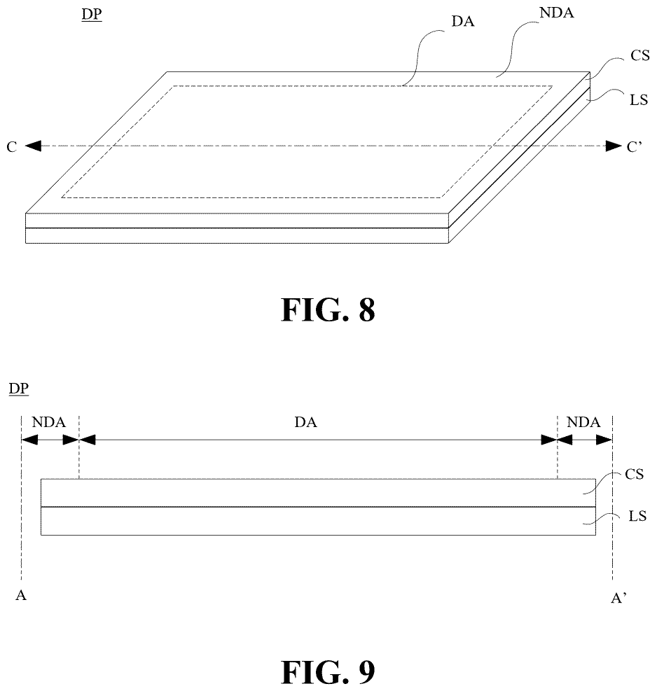

FIG. 8 is a schematic diagram illustrating the structure of a display panel in some embodiments according to the present disclosure. FIG. 9 is a cross-sectional view along an A-A′ line in FIG. 8. Referring to FIG. 8 and FIG. 9, the display panel DP in some embodiments includes a light emitting substrate LS and a color conversion substrate CS. The display panel DP includes a display area DA and a non-display area NDA.

FIG. 10 is a plan view of a display panel in some embodiments according to the present disclosure. Referring to FIG. 10, the display panel in some embodiments includes a plurality of subpixel region SR and an inter-subpixel region ISR.

Various appropriate implementations may be practiced to make a display panel of the present disclosure. In one example, a light emitting substrate and a color conversion substrate are fabricated respectively, and then assembled together using a filler layer into a display panel. In another example, the color conversion substrate is directly fabricated on the light emitting substrate.

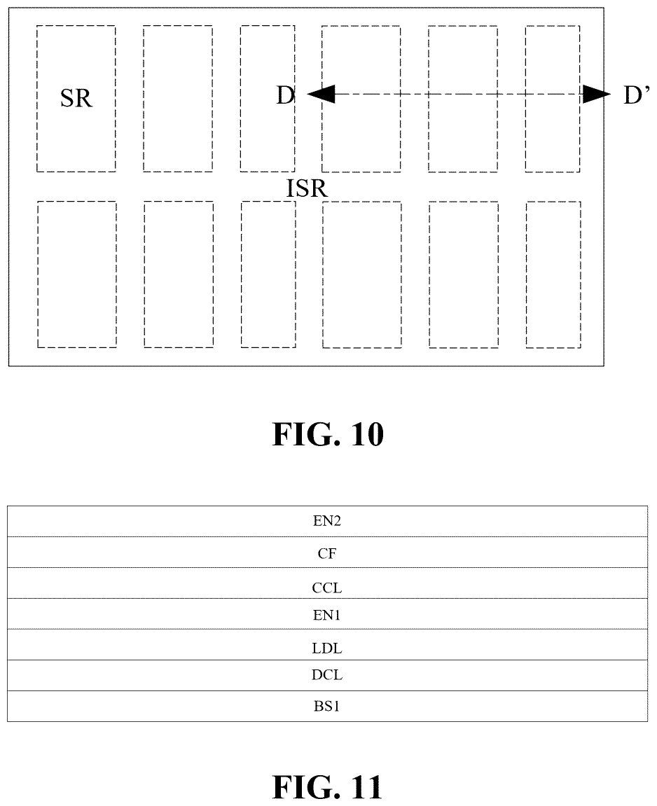

FIG. 11 is a cross-sectional view of a display panel in some embodiments according to the present disclosure. Referring to FIG. 11, the display panel in some embodiments includes a first base substrate BS1, a driving control layer DCL comprising a plurality of transistors configured to control light emission of the display panel on the first base substrate BS1, a light emitting element layer LDL comprising a plurality of light emitting elements on a side of the driving control layer DCL away from the first base substrate BS1, a first encapsulating layer EN1 on a side of the light emitting element layer LDL away from the first base substrate BS1, a color conversion layer CCL on a side of the first encapsulating layer EN1 away from the first base substrate BS1, a color filter CF on a side of the color conversion layer CCL away from the first base substrate BS1, and a second encapsulating layer EN2 on a side of the color filter CF away from the first base substrate BS1.

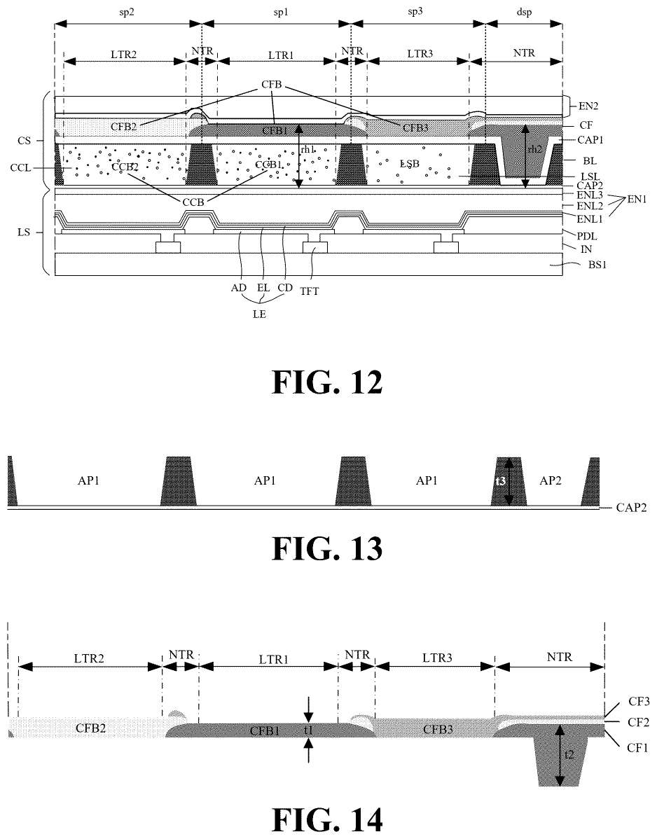

FIG. 12 is a cross-sectional view of a display panel in some embodiments according to the present disclosure. For example, FIG. 12 may be a cross-sectional view along a D-D′ line in the display panel depicted in FIG. 10. Referring to FIG. 12, the display panel in some embodiments includes a light emitting substrate LS and a color conversion substrate CS. The light emitting substrate LS and the color conversion substrate CS are assembled together.

Referring to FIG. 12, in some embodiments, the light emitting substrate LS includes a first base substrate BS1; a plurality of thin film transistor TFT (e.g., transistors in pixel driving circuits) on the first base substrate BS1; an insulating layer IN on a side of the plurality of transistor TFT away from the first base substrate BS1; a pixel definition layer PDL and a plurality of light emitting elements LE on a side of the insulating layer IN away from the first base substrate BS1; and a first encapsulating layer EN1 on a side of the plurality of light emitting elements LE and the pixel definition layer PDL away from the first base substrate BS1. A respective light emitting element of the plurality of light emitting elements LE includes an anode AD, a light emitting layer EL on a side of the anode AD away from the first base substrate BS1, and a cathode CD on a side of the light emitting layer EL away from the first base substrate BS1. In one example, the first encapsulating layer EN1 include a first inorganic encapsulating sublayer ENL1, a first organic encapsulating sublayer ENL2 on a side of the first inorganic encapsulating sublayer ENL1 away from the first base substrate BS1, and a second inorganic encapsulating sublayer ENL3 on a side of the first organic encapsulating sublayer ENL2 away from the first base substrate BS1.

In some embodiments, the color conversion substrate CS includes a second cap layer CAP2 on the first encapsulating layer EN1, a bank layer BL defining a plurality of first apertures, a color conversion layer CCL and a light scattering layer LSL at least partially in the plurality of first apertures defined by the bank layer BL. The color conversion layer CCL includes a plurality of color conversion blocks CCB including a first color conversion block CCB1 of a first color and a second color conversion block CCB2 of a second color. The light scattering layer LSL includes a plurality of light scattering blocks LSB.

In some embodiments, the color conversion substrate CS further includes a plurality of second apertures extending through the bank layer BL. FIG. 13 illustrates a plurality of first apertures and a plurality of second apertures in a color conversion substrate in some embodiments according to the present disclosure. Referring to FIG. 12 and FIG. 13, the plurality of first apertures AP1 and the plurality of second apertures AP2 are in the display area DA of the color conversion substrate CS. In some embodiments, the plurality of first apertures AP1 are configured to receive the plurality of color conversion blocks CCB and the plurality of light scattering blocks LSB. The plurality of color conversion blocks CCB and the plurality of light scattering blocks LSB are absent in the plurality of second apertures AP2.

In some embodiments, the display panel includes a plurality of first subpixels sp1, a plurality of second subpixels sp2, a plurality of third subpixels sp3, and a plurality of dummy subpixels dsp. A respective subpixel of the plurality of first subpixels sp1, the plurality of second subpixels sp2, or the plurality of third subpixels sp3 includes a respective light emitting element of the plurality of light emitting elements LE. The plurality of light emitting elements LE are absent in the plurality of dummy subpixels dsp.

In some embodiments, the display panel includes a first light transmissive region LTR1 in the first subpixel sp1, a second light transmissive region LTR2 in the second subpixel sp2, a third light transmissive region LTR3 in the third subpixel sp3, and a light non-transmissive region NTR. In some embodiments, the color conversion layer CCL includes a plurality of color conversion blocks CCB including a first color conversion block CCB1 and a second color conversion block CCB2. The light scattering layer includes a plurality of light scattering blocks LSB. The first color conversion block CCB1 is at least partially in the first light transmissive region LTR1. The second color conversion block CCB2 is at least partially in the second light transmissive region LTR2. A respective light scatter block of the plurality of light scattering blocks LSB is at least partially in the third light transmissive region LTR3.

In some embodiments, the display panel includes a bank layer BL in the light non-transmissive region NTR. In some embodiments, the plurality of dummy subpixels dsp are in the light non-transmissive region NTR.

In some embodiments, the color conversion substrate CS further includes a first cap layer CAP1 on a side of the bank layer BL, the color conversion layer CCL, and the light scattering layer LSL away from the second cap layer CAP2. In some embodiments, the first cap layer CAP1 includes an inorganic insulating material. In some embodiments, the second cap layer CAP2 includes an inorganic insulating material.

In some embodiments, the first cap layer CAP1 is in direct contact with the plurality of color conversion blocks CCB and in direct contact with the plurality of light scattering blocks LSB. In some embodiments, a portion of the first cap layer CAP1 is in a respective second aperture of the plurality of second apertures AP2. In some embodiments, the portion of the first cap layer CAP1 in the respective second aperture is in direct contact with the second cap layer CAP2. Optionally, the first cap layer CAP1 is in direct contact with the bank layer BL.

In some embodiments, the second cap layer CAP2 is in direct contact with the plurality of color conversion blocks CCB and in direct contact with the plurality of light scattering blocks LSB. Optionally, the second cap layer CAP2 is in direct contact with the bank layer BL.

In some embodiments, the color conversion substrate CS further includes a color filter CF on a side of the first cap layer CAP1 away from the bank layer BL, the color conversion layer CCL, and the light scattering layer LSL. The color filter CF includes a plurality of color filter blocks CFB. An orthographic projection of a respective color filter block of the plurality of color filter blocks CFB on a base substrate at least partially overlaps with an orthographic projection of a respective color conversion block or a respective light scattering block on the base substrate. Orthographic projections of adjacent color filter blocks may partially overlap with each other, e.g., along the edges.

In some embodiments, the first cap layer CAP1 is in direct contact with the color filter CF. The inventors of the present disclosure discover that, by having the first cap layer CAP1 in direct contact with the color filter CF, in direct contact with the plurality of color conversion blocks CCB, and in direct contact with the plurality of light scattering blocks LSB, the optical distance between the color filter and the color conversion layer CCL can be reduced, preventing color shift issues and improving display quality.

In some embodiments, the second cap layer CAP2 is in direct contact with the first encapsulating layer EN1.

In some embodiments, the plurality of color filter blocks CFB include a first color filter block CFB1, a second color filter block CFB2, and a third color filter block CFB3. An orthographic projection of the first color filter block CFB1 on a base substrate at least partially overlaps with an orthographic projection of the first color conversion block CCB1 on the base substrate. An orthographic projection of the second color filter block CFB2 on a base substrate at least partially overlaps with an orthographic projection of the second color conversion block CCB2 on the base substrate. An orthographic projection of the third color filter block CFB3 on a base substrate at least partially overlaps with an orthographic projection of a respective light scattering block of the plurality of light scattering blocks LSB on the base substrate.

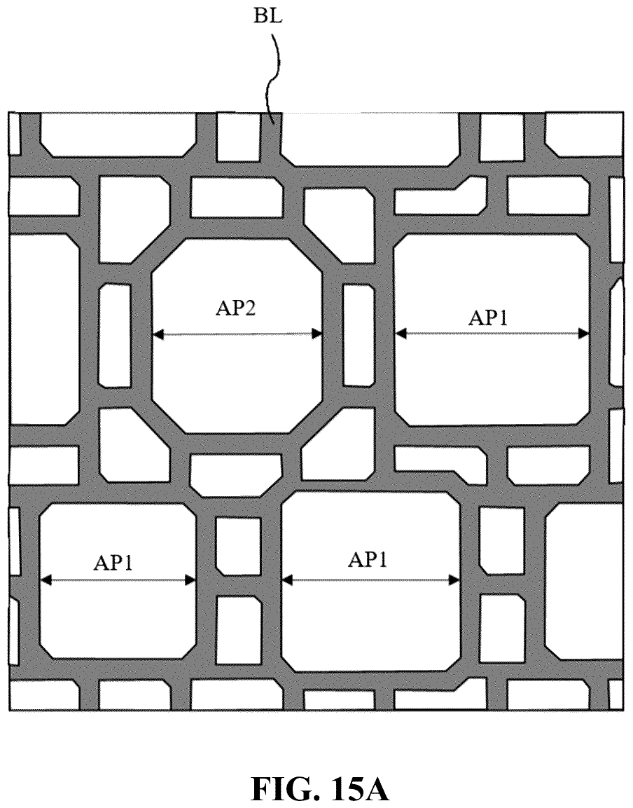

FIG. 14 illustrates a color filter in a color conversion substrate in some embodiments according to the present disclosure. Referring to FIG. 12 to FIG. 14, the color filter CF in some embodiments includes a first color filter layer CF1 of a first color, a second color filter layer CF2 of a second color on the first color filter layer CF1 of the first color, and a third color filter layer CF3 of a third color on a side of the second color filter layer CF2 of the second color away from the first color filter layer CF1 of the first color. In some embodiments, the first color, the second color, and the third color are three different colors selected from a green color, a red color, and a blue color. In one example, the first color is a green color, the second color is a red color, and the third color is a blue color.

In some embodiments, in at least a portion of the light non-transmissive region NTR between two adjacent light transmissive regions (e.g., between a first light transmissive region LTR1 and a second light transmissive region LTR2 or between a second light transmissive region LTR2 and a third light transmissive region LTR3 or between a first light transmissive region LTR1 and a third light transmissive region LTR3), the color conversion substrate includes a stacked structure comprising at least two of a portion of the first color filter layer CF1 of the first color, a portion of the second color filter layer CF2 of the second color on the portion of the first color filter layer CF1 of the first color, or a portion of the third color filter layer CF3 of the third color on a side of the portion of the second color filter layer CF2 of the second color away from the portion of the first color filter layer CF1 of the first color. Optionally, in at least a portion of the light non-transmissive region NTR between two adjacent light transmissive regions, the color conversion substrate includes a stacked structure comprising a portion of the first color filter layer CF1 of the first color, a portion of the second color filter layer CF2 of the second color on the portion of the first color filter layer CF1 of the first color, and a portion of the third color filter layer CF3 of the third color on a side of the portion of the second color filter layer CF2 of the second color away from the portion of the first color filter layer CF1 of the first color. The stacked structure in the portion of the light non-transmissive region NTR functions as a black matrix blocking light.

In some embodiments, in a portion of the light non-transmissive region NTR comprising a respective dummy subpixel of the plurality of dummy subpixels dsp, the color conversion substrate includes a stacked structure comprising at least two of a portion of the first color filter layer CF1 of the first color, a portion of the second color filter layer CF2 of the second color on the portion of the first color filter layer CF1 of the first color, or a portion of the third color filter layer CF3 of the third color on a side of the portion of the second color filter layer CF2 of the second color away from the portion of the first color filter layer CF1 of the first color. Optionally, in the portion of the light non-transmissive region NTR comprising a respective dummy subpixel of the plurality of dummy subpixels dsp, the color conversion substrate includes a stacked structure comprising a portion of the first color filter layer CF1 of the first color, a portion of the second color filter layer CF2 of the second color on the portion of the first color filter layer CF1 of the first color, and a portion of the third color filter layer CF3 of the third color on a side of the portion of the second color filter layer CF2 of the second color away from the portion of the first color filter layer CF1 of the first color.

In some embodiments, a respective dummy subpixel of the plurality of dummy subpixels dsp is between two adjacent pixels. In one example, each of the two adjacent pixels including a first subpixel of the plurality of first subpixels sp1, a second subpixel of the plurality of second subpixels sp2, and a third subpixel of the plurality of third subpixels sp3. The respective dummy subpixel is configured to absorb light emitted from at least one of the two adjacent pixels. The inventors of the present disclosure discover that, by having the plurality of dummy subpixels dsp, light leakage between adjacent pixels can be effectively prevented, improving color characteristics of the color conversion substrate and the display panel.

In some embodiments, a respective second aperture of the plurality of second apertures AP2 is configured to receive at least one of a portion of the first color filter layer CF1 of the first color, a portion of the second color filter layer CF2 of the second color, or a portion of the third color filter layer CF3 of the third color. In one particular example, the respective second aperture is configured to receive a portion of the first color filter layer CF1 of the first color, the portion of the second color filter layer CF2 of the second color on the portion of the first color filter layer CF1 of the first color, and the portion of the third color filter layer CF3 of the third color on a side of the portion of the second color filter layer CF2 of the second color away from the portion of the first color filter layer CF1 of the first color, are outside the respective second aperture. The portion of the first color filter layer CF1 of the first color inside the respective second aperture is in direct contact with a portion of the first cap layer CAP1 inside the respective second aperture.

In some embodiments, the first color is a green color, the second color is a red color, and the third color is a blue color.

In alternative embodiments, the first color is a red color, the second color is a green color, and the third color is a blue color.

In some embodiments, along a plane intersecting two adjacent color filter blocks and perpendicular to a surface of the first encapsulating layer EN1, a portion of the first color filter layer CF1 of the first color in a portion of a light transmissive region comprising a first aperture of the plurality of first apertures (e.g., the first color filter block CFB1) has a first thickness t1; a portion of the first color filter layer CF1 of the first color in a portion of a light non-transmissive region comprising a second aperture of the plurality of second apertures has a second thickness t2. Optionally, the second thickness t2 is greater than the first thickness t1. In some embodiments, along the plane intersecting two adjacent color filter blocks and perpendicular to the surface of the first encapsulating layer EN1, the bank layer BL has a third thickness t3. Optionally, a difference between the second thickness t2 and the first thickness t1 is substantially the same as the third thickness t3. As used herein, the term “substantially the same” refers to a difference between two values not exceeding 10% of a base value (e.g., one of the two values), e.g., not exceeding 8%, not exceeding 6%, not exceeding 4%, not exceeding 2%, not exceeding 1%, not exceeding 0.5%, not exceeding 0.1%, not exceeding 0.05%, and not exceeding 0.01%, of the base value.

In some embodiments, a surface of the portion of the first color filter layer CF1 of the first color in the portion of the light transmissive region comprising the first aperture of the plurality of first apertures (e.g., the first color filter block CFB1) on a side away from the surface of the first encapsulating layer EN1 has a first relative height rh1 with respect to the surface of the first encapsulating layer EN1, and a surface of the portion of the first color filter layer CF1 of the first color in the portion of the light non-transmissive region comprising the second aperture of the plurality of second apertures on a side away from the surface of the first encapsulating layer EN1 has a second relative height rh2 with respect to the surface of the first encapsulating layer EN1. Optionally, the first relative height rh1 and the second relative height rh2 are substantially the same.

In some embodiments, the color conversion substrate further includes a second encapsulating layer EN2 on a side of the color filter CF away from the first cap layer CAP1.

The second encapsulating layer EN2 includes at least one inorganic encapsulating sublayer and/or at least one organic encapsulating sublayer.

In some embodiments, referring to FIG. 11 to FIG. 14, a ratio of a combined thickness of the first encapsulating layer EN1 and the second encapsulating layer EN2 to a thickness of the bank layer BL is in a range of 3:11 to 6:10. In one particular example, a thickness of the first encapsulating layer EN1 is in a range of 3 μm to 6 μm.

In some embodiments, a thickness of the first encapsulating layer EN1 is greater than a thickness of the second encapsulating layer EN2. Optionally, a thickness of the first organic encapsulating sublayer ENL2 of the first encapsulating layer EN1 is greater than a thickness of an organic encapsulating sublayer of the second encapsulating layer EN2.

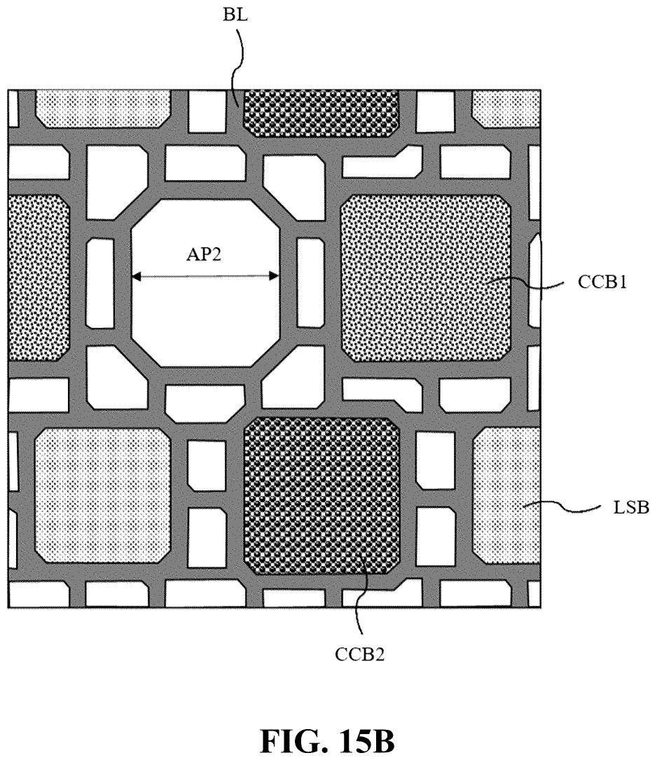

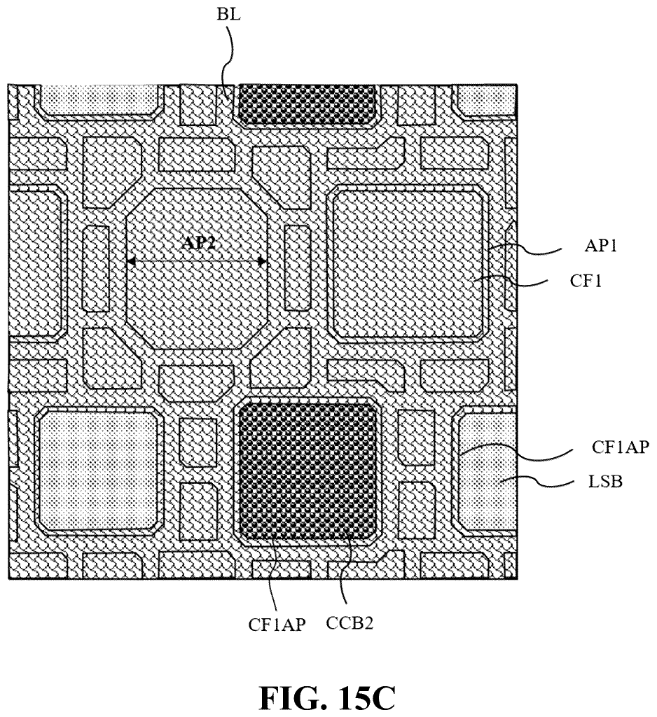

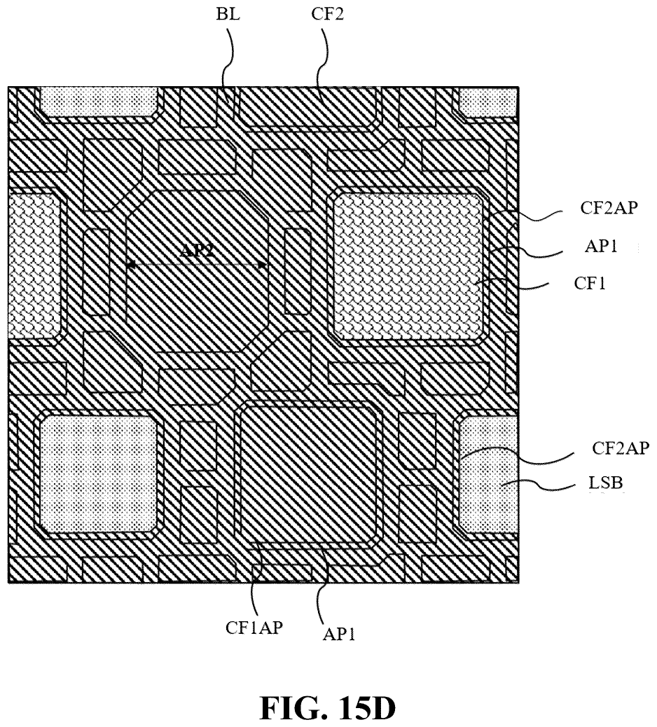

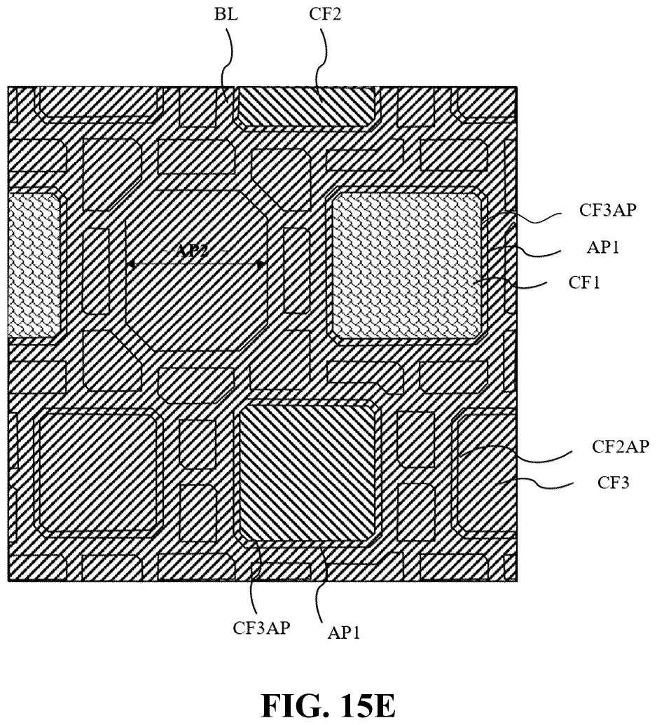

FIG. 15A to FIG. 15E illustrate a process of fabricating a color conversion substrate in some embodiments according to the present disclosure. Referring to FIG. 15A, a bank layer BL is formed, and a plurality of first apertures AP1 and a plurality of second apertures AP2 are formed extending through the bank layer BL. The plurality of first apertures AP1 and the plurality of second apertures AP2 are formed in the display area of the color conversion substrate.

In some embodiments, prior to forming the bank layer BL, a second cap layer is formed. The bank layer BL is formed on the second cap layer.

Referring to FIG. 15B, a plurality of color conversion blocks including a first color conversion block CCB1 and a second color conversion block CCB2, and a plurality of light scattering blocks LSB, are formed at least partially in the plurality of first apertures AP1. The plurality of color conversion blocks and the plurality of light scattering blocks LSB are not formed in the plurality of second apertures AP2.

Subsequently, a first cap layer is formed on a side of the plurality of color conversion blocks, the plurality of light scattering blocks LSB, and the bank layer BL away from the second cap layer.

Referring to FIG. 15C, a first color filter layer CF1 of a first color is formed on a side of the first cap layer away from the plurality of color conversion blocks, the plurality of light scattering blocks LSB, and the bank layer BL. A plurality of first color filter apertures CF1AP extend through the first color filter layer CF1 of the first color. The first color filter layer CF1 of the first color is formed in at least one of the plurality of first apertures AP1 at least partially receiving the first color conversion block CCB1, the second color conversion block CCB2, or the respective light scattering block of the plurality of light scattering blocks LSB. In FIG. 15C, the first color filter layer CF1 of the first color is formed in a first aperture of the plurality of first apertures AP1 at least partially receiving the first color conversion block CCB1. The first color filter layer CF1 of the first color is at least partially absent (e.g., completely absent) in first apertures of the plurality of first apertures AP1 at least partially receiving the second color conversion block CCB2 and the respective light scattering block of the plurality of light scattering blocks LSB. The plurality of first color filter apertures CF1AP expose the second color conversion block CCB2 and the respective light scattering block of the plurality of light scattering blocks LSB.

The first color filter layer CF1 of the first color is formed in the plurality of second apertures AP2. The first color filter layer CF1 of the first color is also formed at least partially in the light non-transmissive region NTR having the bank layer BL.

Referring to FIG. 15D, a second color filter layer CF2 of a second color is formed on a side of the first color filter layer CF1 of the first color away from the first cap layer. A plurality of second color filter apertures CF2AP extend through the second color filter layer CF2 of the second color. The second color filter layer CF2 of the second color is formed in at least one of the plurality of first apertures AP1 at least partially receiving the first color conversion block CCB1, the second color conversion block CCB2, or the respective light scattering block of the plurality of light scattering blocks LSB. In FIG. 15D, the second color filter layer CF2 of the second color is formed in a first aperture of the plurality of first apertures AP1 at least partially receiving the second color conversion block CCB2. The second color filter layer CF2 of the second color is at least partially absent (e.g., completely absent) in first apertures of the plurality of first apertures AP1 at least partially receiving the first color conversion block CCB1 and the respective light scattering block of the plurality of light scattering blocks LSB. The plurality of second color filter apertures CF2AP expose a portion of the first color filter CF1 of the first color on the first color conversion block CCB1 and the respective light scattering block of the plurality of light scattering blocks LSB.

The second color filter layer CF2 of the second color is formed on a portion of the first color filter CF1 of the first color in the plurality of second apertures AP2. The second color filter layer CF2 of the second color is also formed at least partially in the light non-transmissive region NTR having the bank layer BL.

Referring to FIG. 15E, a third color filter layer CF3 of a third color is formed on a side of the second color filter layer CF2 of the second color away from the first color filter layer CF1 of the first color. A plurality of third color filter apertures CF3AP extend through the third color filter layer CF3 of the third color. The third color filter layer CF3 of the third color is formed in at least one of the plurality of first apertures AP1 at least partially receiving the first color conversion block CCB1, the second color conversion block CCB2, or the respective light scattering block of the plurality of light scattering blocks LSB. In FIG. 15E, the third color filter layer CF3 of the third color is formed in a first aperture of the plurality of first apertures AP1 at least partially receiving the respective light scattering block of the plurality of light scattering blocks LSB. The third color filter layer CF3 of the third color is at least partially absent (e.g., completely absent) in first apertures of the plurality of first apertures AP1 at least partially receiving the first color conversion block CCB1 and the second color conversion block CCB2. The plurality of third color filter apertures CF3AP expose a portion of the first color filter CF1 of the first color on the first color conversion block CCB1 and a portion of the second color filter CF2 of the second color on the second color conversion block CCB2.

The third color filter layer CF3 of the third color is formed on a side of a portion of the second color filter CF2 of the second color away from a portion of the first color filter CF1 of the first color in the plurality of second apertures AP2. The third color filter layer CF3 of the third color is also formed at least partially in the light non-transmissive region NTR having the bank layer BL.

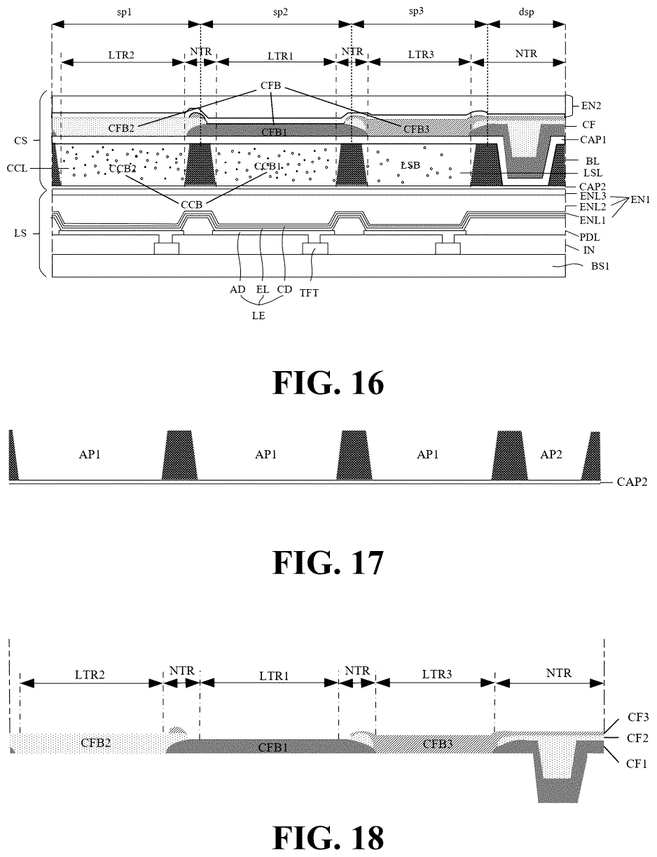

FIG. 16 is a cross-sectional view of a display panel in some embodiments according to the present disclosure. For example, FIG. 16 may be a cross-sectional view along a D-D′ line in the display panel depicted in FIG. 10. FIG. 17 illustrates a plurality of first apertures and a plurality of second apertures in a color conversion substrate in some embodiments according to the present disclosure. FIG. 18 illustrates a color filter in a color conversion substrate in some embodiments according to the present disclosure. Referring to FIG. 16 to FIG. 18, the color filter CF in some embodiments includes a first color filter layer CF1 of a first color, a second color filter layer CF2 of a second color on the first color filter layer CF1 of the first color, and a third color filter layer CF3 of a third color on a side of the second color filter layer CF2 of the second color away from the first color filter layer CF1 of the first color. In some embodiments, the first color, the second color, and the third color are three different colors selected from a green color, a red color, and a blue color. In one example, the first color is a green color, the second color is a red color, and the third color is a blue color.

In some embodiments, in at least a portion of the light non-transmissive region NTR between two adjacent light transmissive regions (e.g., between a first light transmissive region LTR1 and a second light transmissive region LTR2 or between a second light transmissive region LTR2 and a third light transmissive region LTR3 or between a first light transmissive region LTR1 and a third light transmissive region LTR3), the color conversion substrate includes a stacked structure comprising at least two of a portion of the first color filter layer CF1 of the first color, a portion of the second color filter layer CF2 of the second color on the portion of the first color filter layer CF1 of the first color, or a portion of the third color filter layer CF3 of the third color on a side of the portion of the second color filter layer CF2 of the second color away from the portion of the first color filter layer CF1 of the first color. Optionally, in at least a portion of the light non-transmissive region NTR between two adjacent light transmissive regions, the color conversion substrate includes a stacked structure comprising a portion of the first color filter layer CF1 of the first color, a portion of the second color filter layer CF2 of the second color on the portion of the first color filter layer CF1 of the first color, and a portion of the third color filter layer CF3 of the third color on a side of the portion of the second color filter layer CF2 of the second color away from the portion of the first color filter layer CF1 of the first color. The stacked structure in the portion of the light non-transmissive region NTR functions as a black matrix blocking light.

In some embodiments, in a portion of the light non-transmissive region NTR comprising a respective dummy subpixel of the plurality of dummy subpixels dsp, the color conversion substrate includes a stacked structure comprising at least two of a portion of the first color filter layer CF1 of the first color, a portion of the second color filter layer CF2 of the second color on the portion of the first color filter layer CF1 of the first color, or a portion of the third color filter layer CF3 of the third color on a side of the portion of the second color filter layer CF2 of the second color away from the portion of the first color filter layer CF1 of the first color. Optionally, in the portion of the light non-transmissive region NTR comprising a respective dummy subpixel of the plurality of dummy subpixels dsp, the color conversion substrate includes a stacked structure comprising a portion of the first color filter layer CF1 of the first color, a portion of the second color filter layer CF2 of the second color on the portion of the first color filter layer CF1 of the first color, and a portion of the third color filter layer CF3 of the third color on a side of the portion of the second color filter layer CF2 of the second color away from the portion of the first color filter layer CF1 of the first color.

In some embodiments, a respective dummy subpixel of the plurality of dummy subpixels dsp is between two adjacent pixels. In one example, each of the two adjacent pixels including a first subpixel of the plurality of first subpixels sp1, a second subpixel of the plurality of second subpixels sp2, and a third subpixel of the plurality of third subpixels sp3. The respective dummy subpixel is configured to absorb light emitted from at least one of the two adjacent pixels. The inventors of the present disclosure discover that, by having the plurality of dummy subpixels dsp, light leakage between adjacent pixels can be effectively prevented, improving color characteristics of the color conversion substrate and the display panel.

In some embodiments, a respective second aperture of the plurality of second apertures AP2 is configured to receive at least one of a portion of the first color filter layer CF1 of the first color, a portion of the second color filter layer CF2 of the second color, or a portion of the third color filter layer CF3 of the third color. In one particular example, the respective second aperture is configured to receive a portion of the first color filter layer CF1 of the first color and a portion of the second color filter layer CF2 of the second color. The portion of the third color filter layer CF3 of the third color on a side of the portion of the second color filter layer CF2 of the second color away from the portion of the first color filter layer CF1 of the first color is outside the respective second aperture. Optionally, another portion of the second color filter layer CF2 of the second color is outside the respective second aperture, e.g., the second color filter layer CF2 of the second color is partially inside the respective second aperture and partially outside the respective second aperture. The portion of the first color filter layer CF1 of the first color inside the respective second aperture is in direct contact with a portion of the first cap layer CAP1 inside the respective second aperture.

Comparing the color filter CF depicted in FIG. 16 to the color filter CF depicted in FIG. 12, the first color filter layer CF1 of the first color of the color filter CF depicted in FIG. 16 has a thickness less than a thickness of the first color filter layer CF1 of the first color of the color filter CF depicted in FIG. 12. The first color filter layer CF1 of the first color of the color filter CF depicted in FIG. 10 completely fills the respective second aperture, whereas the first color filter layer CF1 of the first color of the color filter CF depicted in FIG. 16 only partially fills the respective second aperture. Thus, a portion of the second color filter layer CF2 of the second color of the color filter CF depicted in FIG. 16 partially fills the respective second aperture.

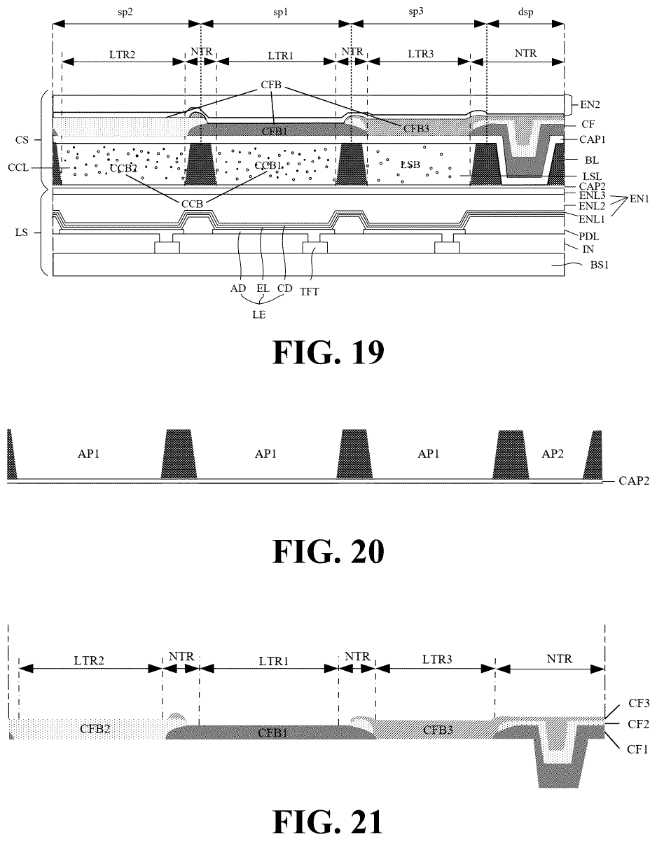

FIG. 19 is a cross-sectional view of a display panel in some embodiments according to the present disclosure. For example, FIG. 19 may be a cross-sectional view along a D-D′ line in the display panel depicted in FIG. 10. FIG. 20 illustrates a plurality of first apertures and a plurality of second apertures in a color conversion substrate in some embodiments according to the present disclosure. FIG. 21 illustrates a color filter in a color conversion substrate in some embodiments according to the present disclosure. Referring to FIG. 19 to FIG. 21, the color filter CF in some embodiments includes a first color filter layer CF1 of a first color, a second color filter layer CF2 of a second color on the first color filter layer CF1 of the first color, and a third color filter layer CF3 of a third color on a side of the second color filter layer CF2 of the second color away from the first color filter layer CF1 of the first color. In some embodiments, the first color, the second color, and the third color are three different colors selected from a green color, a red color, and a blue color. In one example, the first color is a green color, the second color is a red color, and the third color is a blue color.

In some embodiments, in at least a portion of the light non-transmissive region NTR between two adjacent light transmissive regions (e.g., between a first light transmissive region LTR1 and a second light transmissive region LTR2 or between a second light transmissive region LTR2 and a third light transmissive region LTR3 or between a first light transmissive region LTR1 and a third light transmissive region LTR3), the color conversion substrate includes a stacked structure comprising at least two of a portion of the first color filter layer CF1 of the first color, a portion of the second color filter layer CF2 of the second color on the portion of the first color filter layer CF1 of the first color, or a portion of the third color filter layer CF3 of the third color on a side of the portion of the second color filter layer CF2 of the second color away from the portion of the first color filter layer CF1 of the first color. Optionally, in at least a portion of the light non-transmissive region NTR between two adjacent light transmissive regions, the color conversion substrate includes a stacked structure comprising a portion of the first color filter layer CF1 of the first color, a portion of the second color filter layer CF2 of the second color on the portion of the first color filter layer CF1 of the first color, and a portion of the third color filter layer CF3 of the third color on a side of the portion of the second color filter layer CF2 of the second color away from the portion of the first color filter layer CF1 of the first color. The stacked structure in the portion of the light non-transmissive region NTR functions as a black matrix blocking light.

In some embodiments, in a portion of the light non-transmissive region NTR comprising a respective dummy subpixel of the plurality of dummy subpixels dsp, the color conversion substrate includes a stacked structure comprising at least two of a portion of the first color filter layer CF1 of the first color, a portion of the second color filter layer CF2 of the second color on the portion of the first color filter layer CF1 of the first color, or a portion of the third color filter layer CF3 of the third color on a side of the portion of the second color filter layer CF2 of the second color away from the portion of the first color filter layer CF1 of the first color. Optionally, in the portion of the light non-transmissive region NTR comprising a respective dummy subpixel of the plurality of dummy subpixels dsp, the color conversion substrate includes a stacked structure comprising a portion of the first color filter layer CF1 of the first color, a portion of the second color filter layer CF2 of the second color on the portion of the first color filter layer CF1 of the first color, and a portion of the third color filter layer CF3 of the third color on a side of the portion of the second color filter layer CF2 of the second color away from the portion of the first color filter layer CF1 of the first color.

In some embodiments, a respective dummy subpixel of the plurality of dummy subpixels dsp is between two adjacent pixels. In one example, each of the two adjacent pixels including a first subpixel of the plurality of first subpixels sp1, a second subpixel of the plurality of second subpixels sp2, and a third subpixel of the plurality of third subpixels sp3. The respective dummy subpixel is configured to absorb light emitted from at least one of the two adjacent pixels. The inventors of the present disclosure discover that, by having the plurality of dummy subpixels dsp, light leakage between adjacent pixels can be effectively prevented, improving color characteristics of the color conversion substrate and the display panel.

In some embodiments, a respective second aperture of the plurality of second apertures AP2 is configured to receive at least one of a portion of the first color filter layer CF1 of the first color, a portion of the second color filter layer CF2 of the second color, or a portion of the third color filter layer CF3 of the third color. In one particular example, the respective second aperture is configured to receive a portion of the first color filter layer CF1 of the first color, a portion of the second color filter layer CF2 of the second color, and a portion of the third color filter layer CF3 of the third color. Optionally, another portion of the second color filter layer CF2 of the second color is outside the respective second aperture, e.g., the second color filter layer CF2 of the second color is partially inside the respective second aperture and partially outside the respective second aperture. Optionally, another portion of the third color filter layer CF3 of the third color is outside the respective second aperture, e.g., the third color filter layer CF3 of the third color is partially inside the respective second aperture and partially outside the respective second aperture. The portion of the first color filter layer CF1 of the first color inside the respective second aperture is in direct contact with a portion of the first cap layer CAP1 inside the respective second aperture.

Comparing the color conversion substrate depicted in FIG. 19 to the color conversion substrate depicted in FIG. 12 and the color conversion substrate depicted in FIG. 16, the color conversion substrate depicted in FIG. 19 includes three portions of color filters layers of three different colors, enhancing the light leakage blocking ability of the respective dummy subpixel.

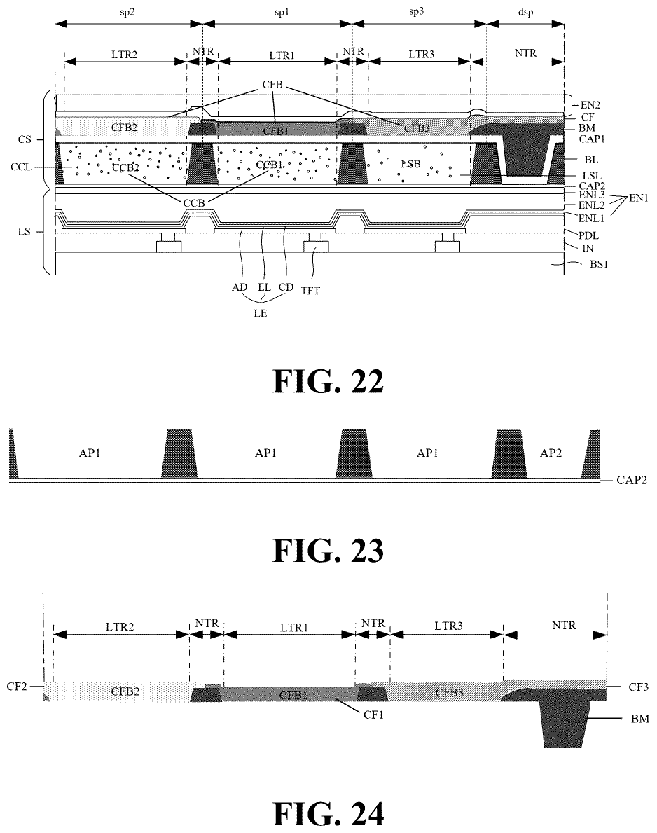

FIG. 22 is a cross-sectional view of a display panel in some embodiments according to the present disclosure. For example, FIG. 22 may be a cross-sectional view along a D-D′ line in the display panel depicted in FIG. 10. Referring to FIG. 22, in some embodiments, the color conversion substrate CS includes a second cap layer CAP2 on the first encapsulating layer EN1, a bank layer BL defining a plurality of first apertures, a color conversion layer CCL and a light scattering layer LSL at least partially in the plurality of first apertures defined by the bank layer BL. The color conversion layer CCL includes a plurality of color conversion blocks CCB including a first color conversion block CCB1 of a first color and a second color conversion block CCB2 of a second color. The light scattering layer LSL includes a plurality of light scattering blocks LSB.

In some embodiments, the color conversion substrate CS further includes a plurality of second apertures extending through the bank layer BL. FIG. 23 illustrates a plurality of first apertures and a plurality of second apertures in a color conversion substrate in some embodiments according to the present disclosure. Referring to FIG. 22 and FIG. 23, the plurality of first apertures AP1 and the plurality of second apertures AP2 are in the display area DA of the color conversion substrate CS. In some embodiments, the plurality of first apertures AP1 are configured to receive the plurality of color conversion blocks CCB and the plurality of light scattering blocks LSB. The plurality of color conversion blocks CCB and the plurality of light scattering blocks LSB are absent in the plurality of second apertures AP2.

In some embodiments, the display panel includes a plurality of first subpixels sp1, a plurality of second subpixels sp2, a plurality of third subpixels sp3, and a plurality of dummy subpixels dsp. A respective subpixel of the plurality of first subpixels sp1, the plurality of second subpixels sp2, or the plurality of third subpixels sp3 includes a respective light emitting element of the plurality of light emitting elements LE. The plurality of light emitting elements LE are absent in the plurality of dummy subpixels dsp.

In some embodiments, the display panel includes a first light transmissive region LTR1 in the first subpixel sp1, a second light transmissive region LTR2 in the second subpixel sp2, a third light transmissive region LTR3 in the third subpixel sp3, and a light non-transmissive region NTR. In some embodiments, the color conversion layer CCL includes a plurality of color conversion blocks CCB including a first color conversion block CCB1 and a second color conversion block CCB2. The light scattering layer includes a plurality of light scattering blocks LSB. The first color conversion block CCB1 is at least partially in the first light transmissive region LTR1. The second color conversion block CCB2 is at least partially in the second light transmissive region LTR2. A respective light scatter block of the plurality of light scattering blocks LSB is at least partially in the third light transmissive region LTR3.

In some embodiments, the display panel includes a bank layer BL in the light non-transmissive region NTR. In some embodiments, the plurality of dummy subpixels dsp are in the light non-transmissive region NTR.

In some embodiments, the color conversion substrate CS further includes a first cap layer CAP1 on a side of the bank layer BL, the color conversion layer CCL, and the light scattering layer LSL away from the second cap layer CAP2. In some embodiments, the first cap layer CAP1 includes an inorganic insulating material. In some embodiments, the second cap layer CAP2 includes an inorganic insulating material.

In some embodiments, the first cap layer CAP1 is in direct contact with the plurality of color conversion blocks CCB and in direct contact with the plurality of light scattering blocks LSB. In some embodiments, a portion of the first cap layer CAP1 is in a respective second aperture of the plurality of second apertures AP2. In some embodiments, the portion of the first cap layer CAP1 in the respective second aperture is in direct contact with the second cap layer CAP2. Optionally, the first cap layer CAP1 is in direct contact with the bank layer BL.

In some embodiments, the second cap layer CAP2 is in direct contact with the plurality of color conversion blocks CCB and in direct contact with the plurality of light scattering blocks LSB. Optionally, the second cap layer CAP2 is in direct contact with the bank layer BL.

In some embodiments, the color conversion substrate CS further includes a color filter CF and a black matrix BM on a side of the first cap layer CAP1 away from the bank layer BL, the color conversion layer CCL, and the light scattering layer LSL. The color filter CF includes a plurality of color filter blocks CFB. An orthographic projection of a respective color filter block of the plurality of color filter blocks CFB on a base substrate at least partially overlaps with an orthographic projection of a respective color conversion block or a respective light scattering block on the base substrate. Orthographic projections of adjacent color filter blocks may partially overlap with each other, e.g., along the edges.

In some embodiments, the black matrix BM is at least partially in the light non-transmissive region NTR. In some embodiments, the black matrix BM is at least partially in at least a portion of the light non-transmissive region NTR between two adjacent light transmissive regions (e.g., between a first light transmissive region LTR1 and a second light transmissive region LTR2 or between a second light transmissive region LTR2 and a third light transmissive region LTR3 or between a first light transmissive region LTR1 and a third light transmissive region LTR3). In some embodiments, the black matrix BM is at least partially in a portion of the light non-transmissive region NTR comprising a respective dummy subpixel of the plurality of dummy subpixels dsp.

In some embodiments, the first cap layer CAP1 is in direct contact with the color filter CF and the black matrix BM. The inventors of the present disclosure discover that, by having the first cap layer CAP1 in direct contact with the color filter CF, in direct contact with the black matrix BM, in direct contact with the plurality of color conversion blocks CCB, and in direct contact with the plurality of light scattering blocks LSB, the optical distance between the color filter and the color conversion layer CCL can be reduced, preventing color shift issues and improving display quality.

In some embodiments, the second cap layer CAP2 is in direct contact with the first encapsulating layer EN1.

In some embodiments, the plurality of color filter blocks CFB include a first color filter block CFB1, a second color filter block CFB2, and a third color filter block CFB3. An orthographic projection of the first color filter block CFB1 on a base substrate at least partially overlaps with an orthographic projection of the first color conversion block CCB1 on the base substrate. An orthographic projection of the second color filter block CFB2 on a base substrate at least partially overlaps with an orthographic projection of the second color conversion block CCB2 on the base substrate. An orthographic projection of the third color filter block CFB3 on a base substrate at least partially overlaps with an orthographic projection of a respective light scattering block of the plurality of light scattering blocks LSB on the base substrate.

FIG. 24 illustrates a color filter in a color conversion substrate in some embodiments according to the present disclosure. Referring to FIG. 22 to FIG. 24, the color filter CF in some embodiments includes a first color filter layer CF1 of a first color, a second color filter layer CF2 of a second color on the first color filter layer CF1 of the first color, and a third color filter layer CF3 of a third color on a side of the second color filter layer CF2 of the second color away from the first color filter layer CF1 of the first color. In some embodiments, the first color, the second color, and the third color are three different colors selected from a green color, a red color, and a blue color. In one example, the first color is a green color, the second color is a red color, and the third color is a blue color.

In some embodiments, in at least a portion of the light non-transmissive region NTR between two adjacent light transmissive regions (e.g., between a first light transmissive region LTR1 and a second light transmissive region LTR2 or between a second light transmissive region LTR2 and a third light transmissive region LTR3 or between a first light transmissive region LTR1 and a third light transmissive region LTR3), the color conversion substrate includes a portion of the black matrix BM. Optionally, in at least a portion of the light non-transmissive region NTR between two adjacent light transmissive regions, the color conversion substrate includes a stacked structure comprising the portion of the black matrix BM, and at least two of a portion of the first color filter layer CF1 of the first color, a portion of the second color filter layer CF2 of the second color, or a portion of the third color filter layer CF3 of the third color, on the portion of the black matrix BM. Optionally, in at least a portion of the light non-transmissive region NTR between a first light transmissive region LTR1 and a second light transmissive region LTR2, the color conversion substrate includes a stacked structure comprising the portion of the black matrix BM, a portion of the first color filter layer CF1 of the first color and a portion of the second color filter layer CF2 of the second color on the portion of the black matrix BM. Optionally, in at least a portion of the light non-transmissive region NTR between a second light transmissive region LTR2 and a third light transmissive region LTR3, the color conversion substrate includes a stacked structure comprising the portion of the black matrix BM, a portion of the second color filter layer CF2 of the second color and a portion of the third color filter layer CF3 of the third color on the portion of the black matrix BM. Optionally, in at least a portion of the light non-transmissive region NTR between a first light transmissive region LTR1 and a third light transmissive region LTR3, the color conversion substrate includes a stacked structure comprising the portion of the black matrix BM, a portion of the first color filter layer CF1 of the first color and a portion of the third color filter layer CF3 of the third color on the portion of the black matrix BM.

In some embodiments, in a portion of the light non-transmissive region NTR comprising a respective dummy subpixel of the plurality of dummy subpixels dsp, the color conversion substrate includes a portion of the black matrix BM. Optionally, in the portion of the light non-transmissive region NTR comprising a respective dummy subpixel of the plurality of dummy subpixels dsp, the color conversion substrate includes a stacked structure comprising a portion of the black matrix BM, and at least one of a portion of the first color filter layer CF1 of the first color, a portion of the second color filter layer CF2 of the second color, or a portion of the third color filter layer CF3 of the third color. Optionally, in the portion of the light non-transmissive region NTR comprising a respective dummy subpixel of the plurality of dummy subpixels dsp, the color conversion substrate includes a stacked structure comprising a portion of the black matrix BM, and a portion of the third color filter layer CF3 of the third color.

In some embodiments, a respective dummy subpixel of the plurality of dummy subpixels dsp is between two adjacent pixels. In one example, each of the two adjacent pixels including a first subpixel of the plurality of first subpixels sp1, a second subpixel of the plurality of second subpixels sp2, and a third subpixel of the plurality of third subpixels sp3. The respective dummy subpixel is configured to absorb light emitted from at least one of the two adjacent pixels. The inventors of the present disclosure discover that, by having the plurality of dummy subpixels dsp, light leakage between adjacent pixels can be effectively prevented, improving color characteristics of the color conversion substrate and the display panel.

In some embodiments, a respective second aperture of the plurality of second apertures AP2 is configured to receive a portion of the black matrix BM. The portion of the black matrix BM inside the respective second aperture is in direct contact with a portion of the first cap layer CAP1 inside the respective second aperture.

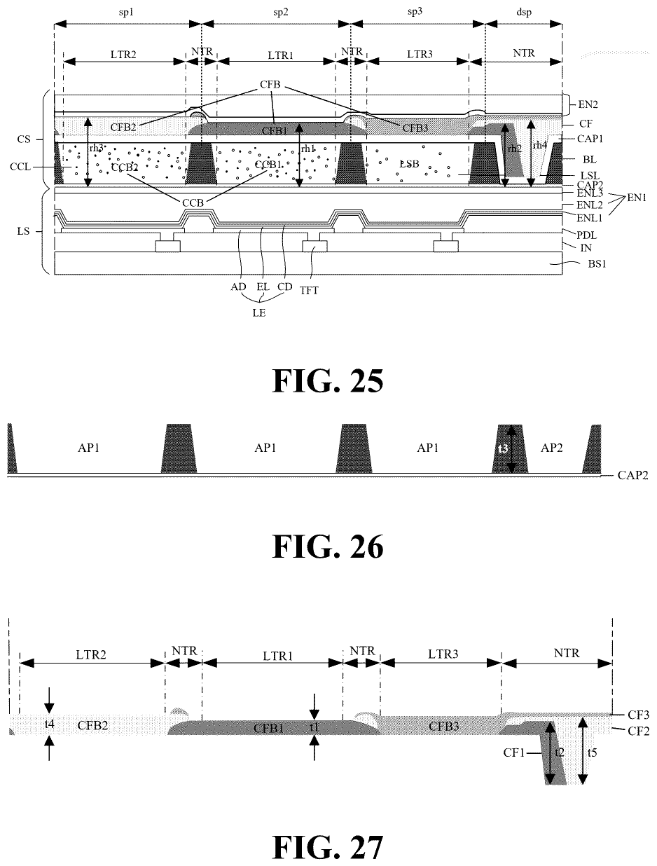

FIG. 25 is a cross-sectional view of a display panel in some embodiments according to the present disclosure. For example, FIG. 25 may be a cross-sectional view along a D-D′ line in the display panel depicted in FIG. 10. FIG. 26 illustrates a plurality of first apertures and a plurality of second apertures in a color conversion substrate in some embodiments according to the present disclosure. FIG. 27 illustrates a color filter in a color conversion substrate in some embodiments according to the present disclosure. Referring to FIG. 25 to FIG. 27, the color filter CF in some embodiments includes a first color filter layer CF1 of a first color, a second color filter layer CF2 of a second color on the first color filter layer CF1 of the first color, and a third color filter layer CF3 of a third color on a side of the second color filter layer CF2 of the second color away from the first color filter layer CF1 of the first color. In some embodiments, the first color, the second color, and the third color are three different colors selected from a green color, a red color, and a blue color. In one example, the first color is a green color, the second color is a red color, and the third color is a blue color.

In some embodiments, in at least a portion of the light non-transmissive region NTR between two adjacent light transmissive regions (e.g., between a first light transmissive region LTR1 and a second light transmissive region LTR2 or between a second light transmissive region LTR2 and a third light transmissive region LTR3 or between a first light transmissive region LTR1 and a third light transmissive region LTR3), the color conversion substrate includes a stacked structure comprising at least two of a portion of the first color filter layer CF1 of the first color, a portion of the second color filter layer CF2 of the second color on the portion of the first color filter layer CF1 of the first color, or a portion of the third color filter layer CF3 of the third color on a side of the portion of the second color filter layer CF2 of the second color away from the portion of the first color filter layer CF1 of the first color. Optionally, in at least a portion of the light non-transmissive region NTR between two adjacent light transmissive regions, the color conversion substrate includes a stacked structure comprising a portion of the first color filter layer CF1 of the first color, a portion of the second color filter layer CF2 of the second color on the portion of the first color filter layer CF1 of the first color, and a portion of the third color filter layer CF3 of the third color on a side of the portion of the second color filter layer CF2 of the second color away from the portion of the first color filter layer CF1 of the first color. The stacked structure in the portion of the light non-transmissive region NTR functions as a black matrix blocking light.

In some embodiments, in a portion of the light non-transmissive region NTR comprising a respective dummy subpixel of the plurality of dummy subpixels dsp, the color conversion substrate includes at least two of a portion of the first color filter layer CF1 of the first color, a portion of the second color filter layer CF2 of the second color, or a portion of the third color filter layer CF3 of the third color. Optionally, in the portion of the light non-transmissive region NTR comprising a respective dummy subpixel of the plurality of dummy subpixels dsp, the color conversion substrate includes a portion of the first color filter layer CF1 of the first color and a portion of the second color filter layer CF2 of the second color.

In some embodiments, a respective dummy subpixel of the plurality of dummy subpixels dsp is between two adjacent pixels. In one example, each of the two adjacent pixels including a first subpixel of the plurality of first subpixels sp1, a second subpixel of the plurality of second subpixels sp2, and a third subpixel of the plurality of third subpixels sp3. The respective dummy subpixel is configured to absorb light emitted from at least one of the two adjacent pixels. The inventors of the present disclosure discover that, by having the plurality of dummy subpixels dsp, light leakage between adjacent pixels can be effectively prevented, improving color characteristics of the color conversion substrate and the display panel.

In some embodiments, a respective second aperture of the plurality of second apertures AP2 is configured to receive at least one of a portion of the first color filter layer CF1 of the first color or a portion of the second color filter layer CF2 of the second color, or a portion of the third color filter layer CF3 of the third color. In one particular example, the respective second aperture is configured to receive a portion of the first color filter layer CF1 of the first color and a portion of the second color filter layer CF2 of the second color. The portion of the third color filter layer CF3 of the third color is outside the respective second aperture. Optionally, the first color filter layer CF1 of the first color is partially inside the respective second aperture and partially outside the respective second aperture. Optionally, the second color filter layer CF2 of the second color is partially inside the respective second aperture and partially outside the respective second aperture. The portion of the first color filter layer CF1 of the first color inside the respective second aperture is in direct contact with a portion of the first cap layer CAP1 inside the respective second aperture. The portion of the second color filter layer CF2 of the second color inside the respective second aperture is in direct contact with a portion of the first cap layer CAP1 inside the respective second aperture.

In some embodiments, the first color is a green color, the second color is a red color, and the third color is a blue color.

In alternative embodiments, the first color is a red color, the second color is a green color, and the third color is a blue color.

In some embodiments, along a plane intersecting two adjacent color filter blocks and perpendicular to a surface of the first encapsulating layer EN1, a portion of the first color filter layer CF1 of the first color in a portion of a light transmissive region comprising a first aperture of the plurality of first apertures (e.g., the first color filter block CFB1) has a first thickness t1; a portion of the first color filter layer CF1 of the first color in a portion of a light non-transmissive region comprising a second aperture of the plurality of second apertures has a second thickness t2. Optionally, the second thickness t2 is greater than the first thickness t1. In some embodiments, along the plane intersecting two adjacent color filter blocks and perpendicular to the surface of the first encapsulating layer EN1, the bank layer BL has a third thickness t3. Optionally, a difference between the second thickness t2 and the first thickness t1 is substantially the same as the third thickness t3. As used herein, the term “substantially the same” refers to a difference between two values not exceeding 10% of a base value (e.g., one of the two values), e.g., not exceeding 8%, not exceeding 6%, not exceeding 4%, not exceeding 2%, not exceeding 1%, not exceeding 0.5%, not exceeding 0.1%, not exceeding 0.05%, and not exceeding 0.01%, of the base value.

In some embodiments, a surface of the portion of the first color filter layer CF1 of the first color in a portion of a light transmissive region comprising a first aperture of the plurality of first apertures (e.g., the first color filter block CFB1) on a side away from the surface of the first encapsulating layer EN1 has a first relative height rh1 with respect to the surface of the first encapsulating layer EN1, and a surface of the portion of the first color filter layer CF1 of the first color in a portion of a light non-transmissive region comprising a second aperture of the plurality of second apertures on a side away from the surface of the first encapsulating layer EN1 has a second relative height rh2 with respect to the surface of the first encapsulating layer EN1. Optionally, the first relative height rh1 and the second relative height rh2 are substantially the same.

In some embodiments, along a plane intersecting two adjacent color filter blocks and perpendicular to a surface of the first encapsulating layer EN1, a portion of the second color filter layer CF2 of the second color in a portion of a light transmissive region comprising a first aperture of the plurality of first apertures (e.g., the second color filter block CFB2) has a fourth thickness t4; a portion of the second color filter layer CF2 of the second color in a portion of a light non-transmissive region comprising a second aperture of the plurality of second apertures has a fifth thickness t5. Optionally, the fifth thickness t5 is greater than the fourth thickness t4. In some embodiments, along the plane intersecting two adjacent color filter blocks and perpendicular to the surface of the first encapsulating layer EN1, the bank layer BL has a third thickness t3. Optionally, a difference between the fifth thickness t5 and the fourth thickness t4 is substantially the same as the third thickness t3.

In some embodiments, a surface of the portion of the second color filter layer CF2 of the second color in the portion of the light transmissive region comprising the first aperture of the plurality of first apertures (e.g., the second color filter block CFB2) on a side away from the surface of the first encapsulating layer EN1 has a third relative height rh3 with respect to the surface of the first encapsulating layer EN1, and a surface of the portion of the second color filter layer CF2 of the second color in the portion of the light non-transmissive region comprising the second aperture of the plurality of second apertures on a side away from the surface of the first encapsulating layer EN1 has a fourth relative height rh4 with respect to the surface of the first encapsulating layer EN1. Optionally, the third relative height rh3 and the fourth relative height rh4 are substantially the same.

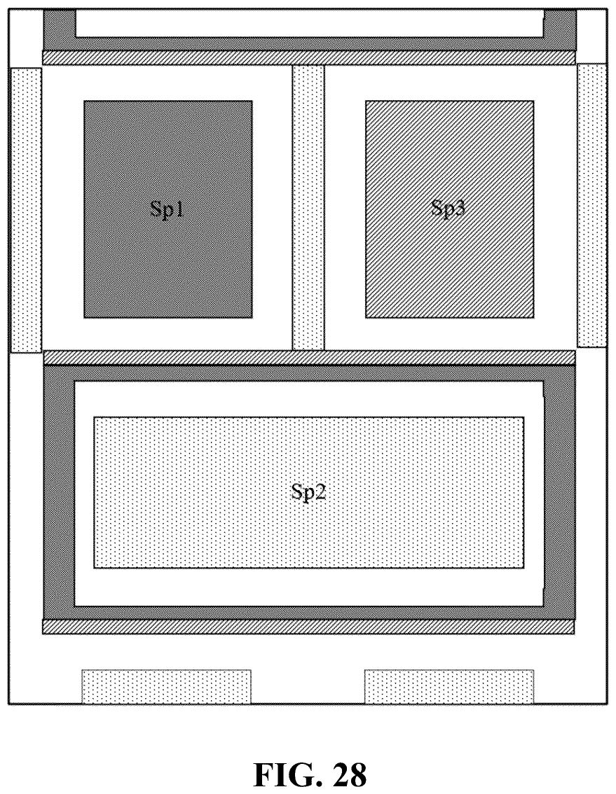

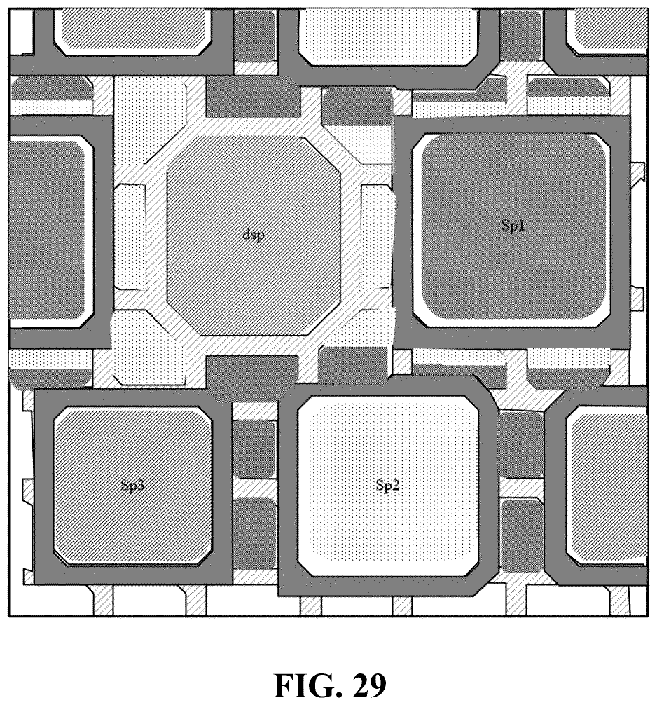

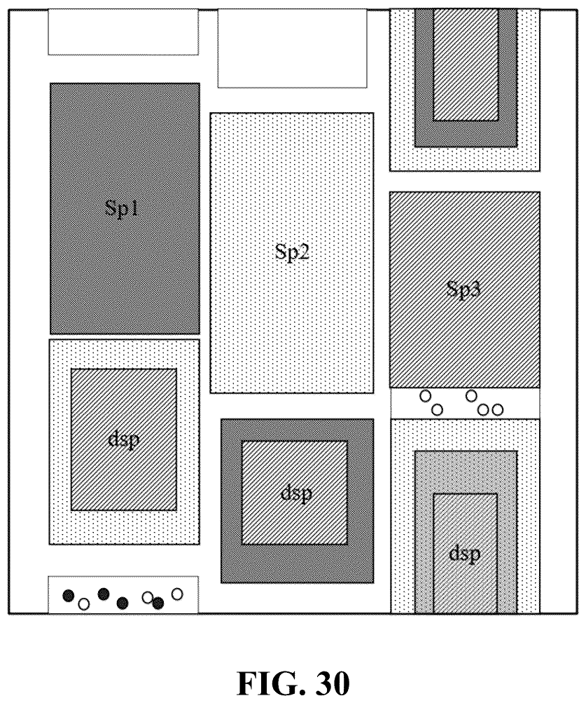

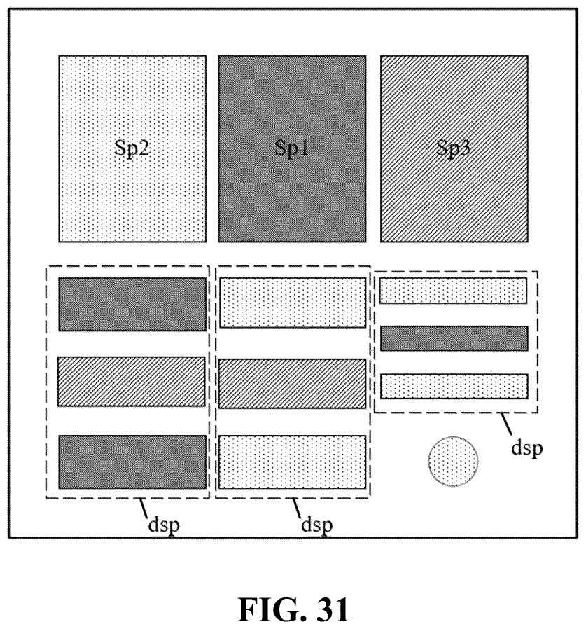

FIG. 28 illustrates a subpixel arrangement in a display panel in some embodiments according to the present disclosure. FIG. 29 illustrates a subpixel arrangement in a display panel in some embodiments according to the present disclosure. FIG. 30 illustrates a subpixel arrangement in a display panel in some embodiments according to the present disclosure. FIG. 31 illustrates a subpixel arrangement in a display panel in some embodiments according to the present disclosure. A plurality of first subpixels sp1, a plurality of second subpixels sp2, a plurality of third subpixels sp3, and a plurality of dummy subpixels dsp are denoted in the display panels depicted in FIG. 28 to FIG. 31,

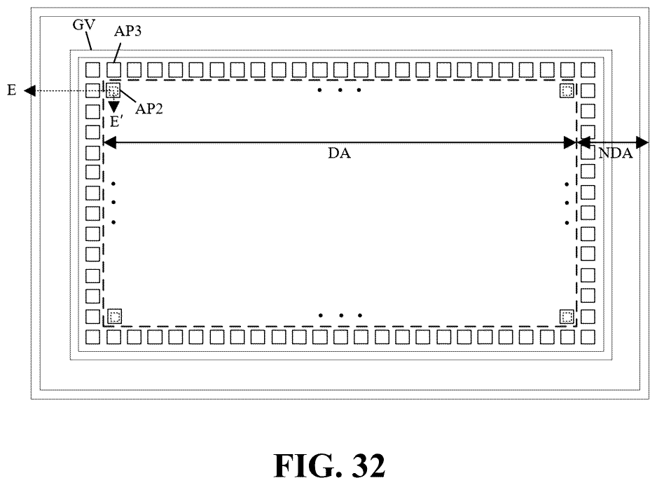

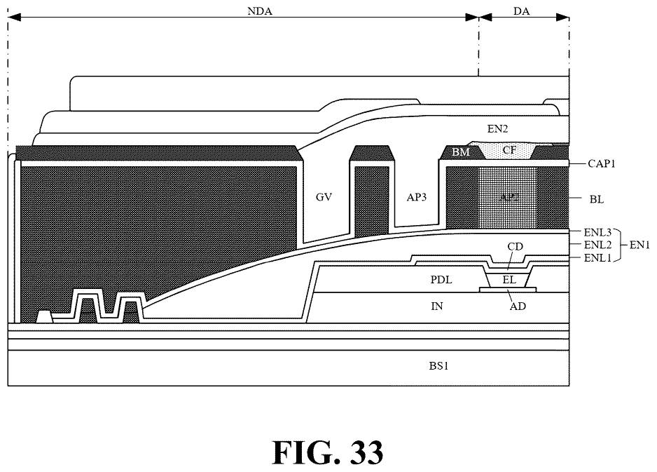

FIG. 32 is a plan view of a display panel in some embodiments according to the present disclosure. FIG. 33 is a cross-sectional view along a E-E′ line in FIG. 32. Referring to FIG. 32 and FIG. 33, the display panel in some embodiments includes a display area DA and a non-display area NDA. In the display area DA, as discussed above, the display panel includes a plurality of first apertures and a plurality of second apertures AP2. In the non-display area NDA, the display panel in some embodiments includes a groove GV extending at least partially into (e.g., extending through) the bank layer BL. The groove GV is in the non-display area NDA.

In some embodiments, the groove GV substantially (e.g., at least 50%, at least 60%, at least 70%, at least 80%, at least 90%, at least 95%, at least 99%, or 100%) surrounds the display area DA.

In some embodiments, the display panel further includes a plurality of third apertures AP3 extending at least partially into (e.g., extending through) the bank layer BL. The plurality of third apertures AP3 are in the non-display area NDA. In some embodiments, a combination of the plurality of third apertures AP3 substantially (e.g., at least 50%, at least 60%, at least 70%, at least 80%, at least 90%, at least 95%, at least 99%, or 100%) surrounds the display area DA.

In some embodiments, the groove GV substantially (e.g., at least 50%, at least 60%, at least 70%, at least 80%, at least 90%, at least 95%, at least 99%, or 100%) surrounds the plurality of third apertures AP3.

In some embodiments, the groove GV is configured to prevent overflow of an encapsulating material (e.g., an organic encapsulating material) during fabrication of the display panel. In some embodiments, a portion of the second encapsulating layer EN2 (for example, at least a portion of an organic encapsulating sublayer of the second encapsulating layer EN2) is at least partially inside the groove GV. In some embodiments, the portion of the second encapsulating layer EN2 (e.g., the portion of the organic encapsulating sublayer of the second encapsulating layer EN2) at least partially inside the groove GV is in direct contact with the first cap layer CAP1.

In some embodiments, a portion of the second encapsulating layer EN2 (for example, at least a portion of an organic encapsulating sublayer of the second encapsulating layer EN2) is at least partially inside a respective third aperture of the plurality of third apertures AP3. In some embodiments, the portion of the second encapsulating layer EN2 (e.g., the portion of the organic encapsulating sublayer of the second encapsulating layer EN2) at least partially inside the respective third aperture is in direct contact with the first cap layer CAP1.

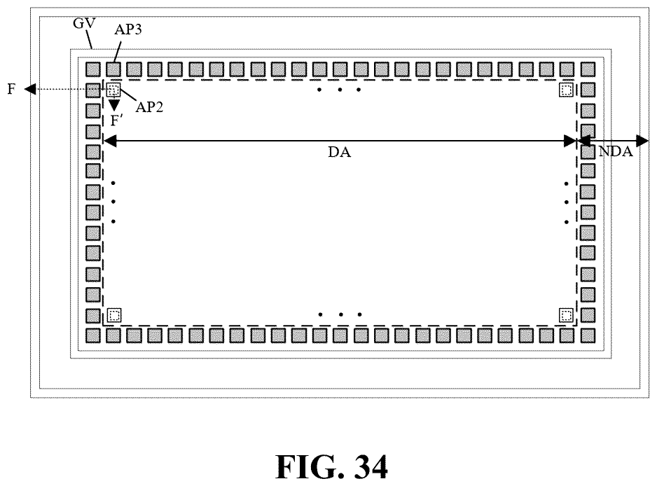

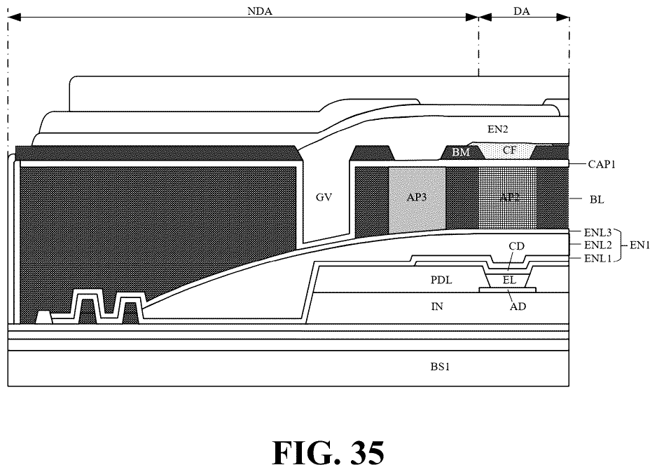

FIG. 34 is a plan view of a display panel in some embodiments according to the present disclosure. FIG. 35 is a cross-sectional view along an F-F′ line in FIG. 34. Referring to FIG. 34 and FIG. 35, the display panel in some embodiments includes a display area DA and a non-display area NDA. In the display area DA, as discussed above, the display panel includes a plurality of first apertures and a plurality of second apertures AP2. In the non-display area NDA, the display panel in some embodiments includes a groove GV extending at least partially into (e.g., extending through) the bank layer BL. The groove GV is in the non-display area NDA.

In some embodiments, the groove GV substantially (e.g., at least 50%, at least 60%, at least 70%, at least 80%, at least 90%, at least 95%, at least 99%, or 100%) surrounds the display area DA.

In some embodiments, the display panel further includes a plurality of third apertures AP3 extending at least partially into (e.g., extending through) the bank layer BL. The plurality of third apertures AP3 are in the non-display area NDA. In some embodiments, a combination of the plurality of third apertures AP3 substantially (e.g., at least 50%, at least 60%, at least 70%, at least 80%, at least 90%, at least 95%, at least 99%, or 100%) surrounds the display area DA.

In some embodiments, the groove GV substantially (e.g., at least 50%, at least 60%, at least 70%, at least 80%, at least 90%, at least 95%, at least 99%, or 100%) surrounds the plurality of third apertures AP3.

In some embodiments, the groove GV is configured to prevent overflow of an encapsulating material (e.g., an organic encapsulating material) during fabrication of the display panel. In some embodiments, a portion of the second encapsulating layer EN2 (for example, at least a portion of an organic encapsulating sublayer of the second encapsulating layer EN2) is at least partially inside the groove GV. In some embodiments, the portion of the second encapsulating layer EN2 (e.g., the portion of the organic encapsulating sublayer of the second encapsulating layer EN2) at least partially inside the groove GV is in direct contact with the first cap layer CAP1.

In some embodiments, at least an organic encapsulating sublayer of the second encapsulating layer EN2 (e.g., an entirety of the second encapsulating layer EN2) is substantially (e.g., at least 50%, at least 60%, at least 70%, at least 80%, at least 90%, at least 95%, at least 99%, or 100%) absent in the plurality of third apertures AP3. In some embodiments, the first cap layer CAP1 spaces apart the second encapsulating layer EN2 from the plurality of third apertures AP3. The first cap layer CAP1 forms top surfaces of the plurality of third apertures AP3.

In some embodiments, the display panel further includes a quantum dots material at least partially inside a respective third aperture of the plurality of third apertures AP3. Optionally, the quantum dots material at least partially inside the respective third aperture is the same as a color conversion material for forming the color conversion layer. By having the quantum dots material at least partially inside a respective third aperture of the plurality of third apertures AP3, a consistency in a printing process of the color conversion layer can be achieved.

In some embodiments, the quantum dots material at least partially inside the respective third aperture is in direct contact with the first cap layer CAP1.

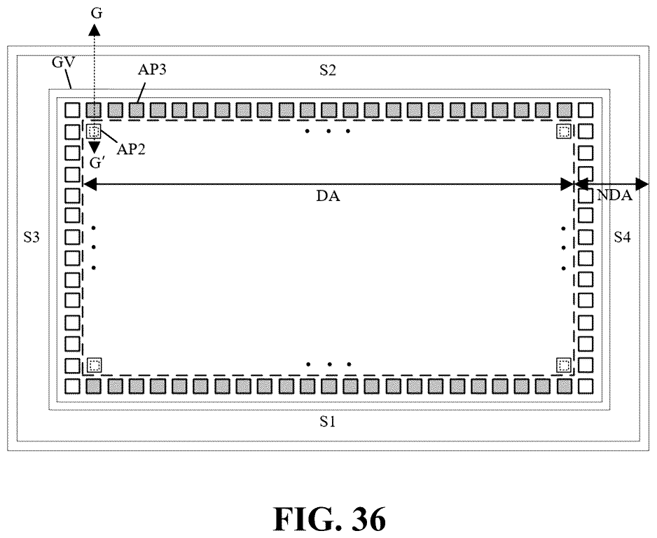

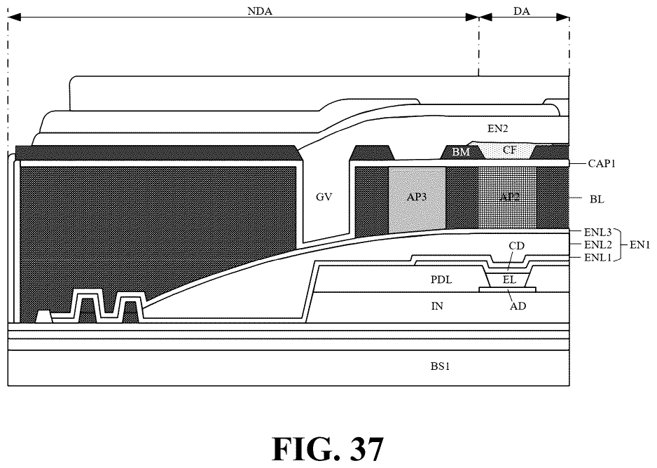

FIG. 36 is a plan view of a display panel in some embodiments according to the present disclosure. FIG. 37 is a cross-sectional view along a G-G′ line in FIG. 36. The display panel depicted in FIG. 36 and FIG. 37 differs from the display panel depicted in FIG. 34 and FIG. 35 in that not all third apertures of the plurality of third apertures AP3 contain a quantum dots material.

In some embodiments, the display panel further includes a quantum dots material at least partially inside a third aperture of the plurality of third apertures AP3 on a first side S1 or a second side S2 of the display area DA, and quantum dots material is absent in a third aperture of the plurality of third apertures AP3 on a third side S3 or a fourth side S4 of the display area DA. The first side S1 is opposite to the second side S2, the third side S3 is opposite to the fourth side S4. The third side S3 connects the first side S1 and the second side S2. The fourth side S4 connects the first side S1 and the second side S2. Optionally, the display panel further includes a quantum dots material at least partially inside third apertures on a first side S1 or a second side S2 of the display area DA, and quantum dots material is absent in third apertures on a third side S3 or a fourth side S4 of the display area DA.

In some embodiments, the color conversion layer and the quantum dots material in the third apertures on a first side S1 or a second side S2 of the display area DA are printed along a direction from the first side S1 to the second side S2, or from the second side S2 to the first side S1.

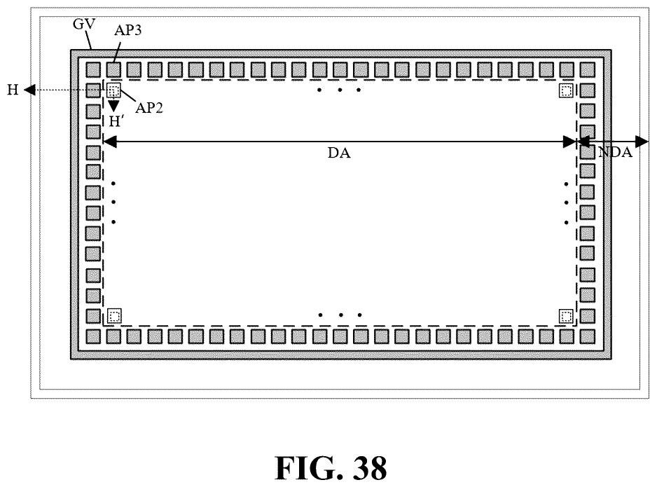

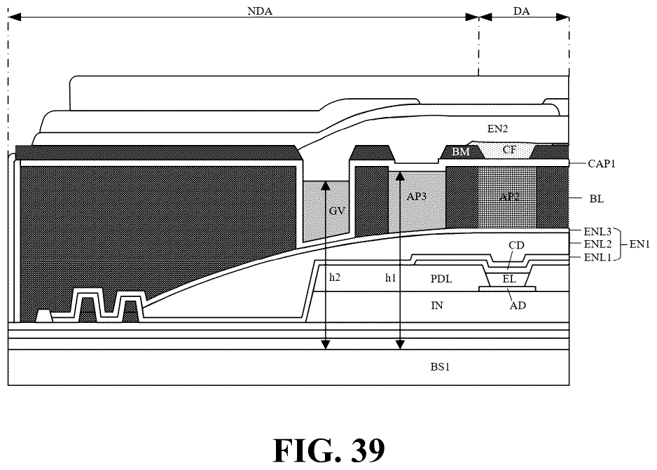

FIG. 38 is a plan view of a display panel in some embodiments according to the present disclosure. FIG. 39 is a cross-sectional view along an H-H′ line in FIG. 38. Referring to FIG. 38 and FIG. 39, the display panel in some embodiments includes a display area DA and a non-display area NDA. In the display area DA, as discussed above, the display panel includes a plurality of first apertures and a plurality of second apertures AP2. In the non-display area NDA, the display panel in some embodiments includes a groove GV extending at least partially into (e.g., extending through) the bank layer BL. The groove GV is in the non-display area NDA.

In some embodiments, the groove GV substantially (e.g., at least 50%, at least 60%, at least 70%, at least 80%, at least 90%, at least 95%, at least 99%, or 100%) surrounds the display area DA.

In some embodiments, the display panel further includes a plurality of third apertures AP3 extending at least partially into (e.g., extending through) the bank layer BL. The plurality of third apertures AP3 are in the non-display area NDA. In some embodiments, a combination of the plurality of third apertures AP3 substantially (e.g., at least 50%, at least 60%, at least 70%, at least 80%, at least 90%, at least 95%, at least 99%, or 100%) surrounds the display area DA.

In some embodiments, the groove GV substantially (e.g., at least 50%, at least 60%, at least 70%, at least 80%, at least 90%, at least 95%, at least 99%, or 100%) surrounds the plurality of third apertures AP3.

In some embodiments, the display panel further includes a quantum dots material at least partially inside the groove GV. Optionally, the quantum dots material at least partially inside the groove GV is the same as a color conversion material for forming the color conversion layer.

In some embodiments, the quantum dots material at least partially inside the groove GV is in direct contact with the first cap layer CAP1.

In some embodiments, the groove GV is configured to prevent overflow of an encapsulating material (e.g., an organic encapsulating material) during fabrication of the display panel. In some embodiments, a portion of the second encapsulating layer EN2 (for example, at least a portion of an organic encapsulating sublayer of the second encapsulating layer EN2) is at least partially inside the groove GV. In some embodiments, the portion of the second encapsulating layer EN2 (e.g., the portion of the organic encapsulating sublayer of the second encapsulating layer EN2) at least partially inside the groove GV is in direct contact with the first cap layer CAP1. Optionally, the portion of the second encapsulating layer EN2 (e.g., the portion of the organic encapsulating sublayer of the second encapsulating layer EN2) at least partially inside the groove GV is in direct contact with the quantum dots material at least partially inside the groove GV.

In some embodiments, at least an organic encapsulating sublayer of the second encapsulating layer EN2 (e.g., an entirety of the second encapsulating layer EN2) is substantially (e.g., at least 50%, at least 60%, at least 70%, at least 80%, at least 90%, at least 95%, at least 99%, or 100%) absent in the plurality of third apertures AP3. In some embodiments, the first cap layer CAPI spaces apart the second encapsulating layer EN2 from the plurality of third apertures AP3. The first cap layer CAP1 forms top surfaces of the plurality of third apertures AP3.

In some embodiments, the display panel further includes a quantum dots material at least partially inside a respective third aperture of the plurality of third apertures AP3. Optionally, the quantum dots material at least partially inside the respective third aperture is the same as a color conversion material for forming the color conversion layer. By having the quantum dots material at least partially inside a respective third aperture of the plurality of third apertures AP3, a consistency in a printing process of the color conversion layer can be achieved.

In some embodiments, the quantum dots material at least partially inside the respective third aperture is in direct contact with the first cap layer CAP1.

In some embodiments, a surface of the quantum dots material in the respective third aperture in direct contact with the first cap layer CAP1 has a first height h1 relative to a surface of the first base substrate BS, a surface of the quantum dots material in the groove GV in direct contact with the second encapsulating layer EN2 has a second height h2 relative to a surface of the first base substrate BS. Optionally, the first height h1 is greater than the second height h2.

In another aspect, the present disclosure provides a display panel comprising a color conversion substrate described herein or fabricated by a method described herein, and a light emitting substrate.

In another aspect, the present disclosure provides a display apparatus, comprising the display panel described herein or fabricated by a method described herein, and one or more integrated circuits connected to the display panel. Examples of appropriate display apparatuses include, but are not limited to, an electronic paper, a mobile phone, a tablet computer, a television, a monitor, a notebook computer, a digital album, a GPS, etc.

In another aspect, the present disclosure provides a method of fabricating a display panel. In some embodiments, the method includes forming a plurality of light emitting elements; forming a first encapsulating layer on the plurality of light emitting elements; forming a color conversion layer comprising a plurality of color conversion blocks on a side of the first encapsulating layer away from the plurality of light emitting elements; forming a color filter on a side of the color conversion layer away from the first encapsulating layer; and forming a second encapsulating layer on a side of the color filter away from the color conversion layer. Optionally, the second encapsulating layer comprises at least an organic encapsulating sublayer.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display panel, comprising:
a plurality of light emitting elements;
a first encapsulating layer on the plurality of light emitting elements;
a color conversion layer comprising a plurality of color conversion blocks on a side of the first encapsulating layer away from the plurality of light emitting elements;
a color filter on a side of the color conversion layer away from the first encapsulating layer; and
a second encapsulating layer on a side of the color filter away from the color conversion layer;
wherein the second encapsulating layer comprises at least an organic encapsulating sublayer.

2. The display panel of claim 1, further comprising:
a first cap layer on a side of the color conversion layer away from the first encapsulating layer, and on side of the color filter away from the second encapsulating layer; and
a second cap layer on a side of the first encapsulating layer away from the plurality of light emitting elements, and on a side of the color conversion layer away from the first cap layer;
wherein the color filter is in direct contact with the first cap layer.

3. The display panel of claim 1, wherein the color filter comprises a first color filter layer of a first color, a second color filter layer of a second color on the first color filter layer of the first color, and a third color filter layer of a third color on a side of the second color filter layer of the second color away from the first color filter layer of the first color;
wherein the first color, the second color, and the third color are three different colors selected from a green color, a red color, and a blue color.

4. The display panel of claim 1, further comprising:
a bank layer; and
a plurality of first apertures and a plurality of second apertures extending through the bank layer;
wherein the plurality of first apertures and the plurality of second apertures are in a display area of the display panel;
the plurality of first apertures are configured to receive the plurality of color conversion blocks; and
the plurality of color conversion blocks are absent in the plurality of second apertures.

5. The display panel of claim 4, wherein a portion of the color filter is at least partially in a respective second aperture of the plurality of second apertures.

6. The display panel of claim 4, in a portion of a light non-transmissive region comprising a respective second aperture of the plurality of second apertures, comprising a stacked structure comprising at least two of a portion of a first color filter layer of a first color, a portion of a second color filter layer of a second color on the portion of the first color filter layer of the first color, or a portion of a third color filter layer of a third color on a side of the portion of the second color filter layer of the second color away from the portion of the first color filter layer of the first color.

7. The display panel of claim 5, wherein the respective second aperture is configured to receive a portion of a first color filter layer of a first color.

8. (canceled)

9. The display panel of claim 5, wherein the respective second aperture is configured to receive a portion of a first color filter layer of a first color and a portion of a second color filter layer of a second color.

10. (canceled)

11. The display panel of claim 9, further comprising a first cap layer on a side of the color conversion layer away from the first encapsulating layer, and on side of the color filter away from the second encapsulating layer;
wherein the portion of the first color filter layer of the first color inside the respective second aperture is in direct contact with a portion of the first cap layer inside the respective second aperture.

12. The display panel of claim 9, further comprising a first cap layer on a side of the color conversion layer away from the first encapsulating layer, and on side of the color filter away from the second encapsulating layer;
wherein the portion of the first color filter layer of the first color inside the respective second aperture is in direct contact with a portion of the first cap layer inside the respective second aperture; and
the portion of the second color filter layer of the second color inside the respective second aperture is in direct contact with the portion of the first cap layer inside the respective second aperture.

13. The display panel of claim 5, wherein the respective second aperture is configured to receive a portion of a first color filter layer of a first color, a portion of a second color filter layer of a second color, and a portion of a third color filter of a third color.

14. The display panel of claim 4, further comprising a black matrix;
wherein the respective second aperture is configured to receive a portion of the black matrix.

15. The display panel of claim 1, further comprising:
a bank layer; and
a groove extending at least partially into the bank layer;
wherein the groove is in a non-display area of the display panel; and
the groove substantially surrounds a display area of the display panel.

16. The display panel of claim 15, wherein a portion of the second encapsulating layer is at least partially inside the groove.

17. The display panel of claim 15, further comprising a plurality of third apertures extending at least partially into the bank layer;
wherein the plurality of third apertures are in the non-display area;
a combination of the plurality of third apertures substantially surrounds the display area; and
the groove substantially surrounds the combination of the plurality of third apertures.

18. The display panel of claim 17, wherein a portion of the second encapsulating layer is at least partially inside a respective third aperture of the plurality of third apertures.

19. The display panel of claim 17, comprising a quantum dots material at least partially inside a respective third aperture of the plurality of third apertures.

20. The display panel of claim 17, comprising a quantum dots material at least partially inside a third aperture of the plurality of third apertures on a first side or a second side of the display area;
wherein quantum dots material is absent in a third aperture of the plurality of third apertures on a third side or a fourth side of the display area;
the first side is opposite to the second side; and
the third side is opposite to the fourth side.

21. The display panel of claim 17, further comprising:
a first cap layer on a side of the color conversion layer away from the first encapsulating layer, and on side of the color filter away from the second encapsulating layer;
wherein a quantum dots material is at least partially inside the groove;
a portion of the second encapsulating layer is at least partially inside the groove; and
a quantum dots material is at least partially inside a respective third aperture of the plurality of third apertures;
wherein a surface of the quantum dots material in the respective third aperture in direct contact with the first cap layer has a first height relative to a surface of a first base substrate;
a surface of the quantum dots material in the groove in direct contact with the portion of the second encapsulating layer inside the groove has a second height relative to a surface of the first base substrate; and
the first height is greater than the second height.

22. A display apparatus, comprising the display panel of claim 1, and one or more integrated circuits connected to the display panel.
